(19) United States
(12) Patent Application Publication
(10) Pub. No.: US 2014/0230871 A1
(43) Pub. Date: Aug. 21, 2014

(54) THERMOELECTRIC CONVERSION MATERIAL AND THERMOELECTRIC CONVERSION ELEMENT

(71) Applicant: FUJIFILUM Corporation, Tokyo (JP)

(72) Inventors: Ryo NISHIO, Ashigarakami-gun (JP); Toshiaki AOAI, Ashigarakami-gun (JP); Naoyuki HAYASHI, Ashigarakami-gun (JP); Eri TAKAHASHI, Ashigarakami-gun (JP)

(73) Assignee: FUJIFILM CORPORATION, Tokyo (JP)

(21) Appl. No.: 14/264,601

(22) Filed: Apr. 29, 2014

Related U.S. Application Data
(63) Continuation of application No. PCT/JP2012/077863, filed on Oct. 29, 2012.

(30) Foreign Application Priority Data
Oct. 31, 2011 (JP) 2011-238781
Feb. 15, 2012 (JP) 2012-030836
Jul. 11, 2012 (JP) 2012-155982
Sep. 28, 2012 (JP) 2012-215440

(51) Int. Cl. H01L 35/24

(52) U.S. Cl. CPC H01L 35/24; Y10S 977/742; Y10S 977/948; B82Y 30/00
USPC 136/205; 252/62.3 T; 977/742; 977/948

(57) ABSTRACT

A thermoelectric conversion material containing a carbon nanotube and a conjugated polymer, in which the conjugated polymer at least has, as a repeating unit having a conjugated system, (A) a condensed polycyclic structure in which three or more rings selected from hydrocarbon rings and heterocycles are condensed, and (B) a monocyclic aromatic hydrocarbon ring structure, a monocyclic aromatic heterocyclic structure, or a condensed ring structure including the monocyclic structure; and a thermoelectric conversion element using the same.

### CROSS-REFERENCE TO RELATED APPLICATIONS

This application is a continuation of PCT/JP2012/077863 filed on Oct. 29, 2012 which claims benefit of Japanese Patent Application No. 2011-238781 filed on Oct. 31, 2011, Japanese Patent Application No. 2012-030836 filed on Feb. 15, 2012, Japanese Patent Application No. 2012-155982 filed on Jul. 11, 2012 and Japanese Patent Application No. 2012-215440 filed on Sep. 28, 2012, the subject matters of which are incorporated herein by reference in their entirety.

### FIELD OF THE INVENTION

The present invention relates to a thermoelectric conversion material and a thermoelectric conversion element using the same.

### BACKGROUND OF THE INVENTION

A thermoelectric conversion material that allows mutual conversion between heat energy and electric energy is used for a thermoelectric conversion element such as a thermoelectric generation device and a Peltier device. In thermoelectric generation applying the thermoelectric conversion material or the thermoelectric conversion element, heat energy can be directly converted into electric power, and a movable part is not required, and thus the thermoelectric generation is used for a power supply for a wrist watch operated by body temperature, a power supply for remote districts, a space power supply or the like.

The performance index Z of a thermoelectric conversion material is represented by the following formula (A), and for an enhancement of performance, improvement of the thermopower (thermoelectromotive force) S and the electrical conductivity σ is important.

Figure of merit ZT=S²σT/κ (A)

S (V/K): Thermopower (Seebeck coefficient)

σ (S/m): Electrical conductivity

κ (W/mK): Thermal conductivity

T (K): Absolute temperature

Satisfactory thermoelectric conversion efficiency is required for the thermoelectric conversion material, and one currently mainly put in practical use includes an inorganic material. However, these inorganic materials are expensive and have problems of containing a hazardous substance, or a complicated step for processing the material into the thermoelectric conversion element, or the like. Therefore, research has been advanced for an organic thermoelectric conversion material that can be relatively inexpensively produced and is also easy in processing such as film formation, and a report has been made on a thermoelectric conversion material and element using an electrically conductive polymer.

For example, Patent Literature 1 describes a thermoelectric element using an electrically conductive polymer such as polyaniline, Patent Literature 2 describes a thermoelectric conversion material containing polythienylene vinylene, and Patent Literatures 3 and 4 describe a thermoelectric material formed by doping polyaniline, respectively. Moreover, Patent Literature 5 describes an art for dissolving polyaniline into an organic solvent, spin coating of the resultant material on a substrate and forming a thin film, and a thermoelectric material using the same, but a production process therefor is complicated. Patent Literature 6 describes a thermoelectric conversion material formed of an electrically conductive polymer prepared by doping poly(3-alkylthiophene) with iodine, and reports that thermoelectric conversion characteristics of a practical use level are demonstrated. Patent Literature 7 discloses a thermoelectric conversion material formed of an electrically conductive polymer obtained by performing doping treatment of polyphenylene vinylene or alkoxy-substituted polyphenylene vinylene.

However, these thermoelectric conversion materials are still far from sufficient in thermoelectric conversion efficiency

Carbon nanotube is an organic material that has been paid attention in recent years for having high electrical conductivity. However, carbon nanotubes have low dispersibility, and an enhancement of dispersibility upon practicalization has been a problem to be solved. In regard to a thermoelectric conversion element, it is required that a thermoelectric conversion material is molded into a shape having a certain thickness so that a temperature difference can be maintained at the two ends of the element. Therefore, such low dispersibility poses a more problem.

### CITATION LIST

### Patent Literatures

Patent Literature 1: JP-A-2010-95688 (“JP-A” means unexamined published Japanese patent application)
Patent Literature 2: JP-A-2009-71131
Patent Literature 3: JP-A-2001-326393
Patent Literature 4: JP-A-2000-323758
Patent Literature 5: JP-A-2002-100815
Patent Literature 6: JP-A-2003-332638
Patent Literature 7: JP-A-2003-332639

### SUMMARY OF THE INVENTION

### Problems that the Invention is to Solve

The present invention is contemplated for providing a thermoelectric conversion material having excellent thermoelectric conversion performance, and a thermoelectric conversion element using this material.

### Means to Solve the Problem

Under such circumstances, the inventors of the present invention conducted a thorough investigation on organic thermoelectric conversion materials. As a result, the inventors found that a composition containing a carbon nanotube and a conjugated polymer having a particular structure exhibits excellent thermoelectric conversion performance, and is therefore useful as a thermoelectric conversion material. Further, they found that the dispersibility of carbon nanotubes in the material is satisfactory, and the material is suitable for film formation by coating. The present invention has been made based on these finding.

According to the present invention, there is provided the following means:

<1> A thermoelectric conversion material, comprising a carbon nanotube and a conjugated polymer,

wherein the conjugated polymer at least has, as a repeating unit having a conjugated system,

(A) a condensed polycyclic structure in which three or more rings selected from hydrocarbon rings and heterocycles are condensed, and

(B) a monocyclic aromatic hydrocarbon ring structure, a monocyclic aromatic heterocyclic structure, or a condensed ring structure including the monocyclic structure.

<2> The thermoelectric conversion material according to the item <1>, wherein the repeating unit (B) is a monocyclic aromatic hydrocarbon ring structure, a monocyclic aromatic heterocyclic structure, or a condensed bicyclic structure including the monocyclic structure.
<3> The thermoelectric conversion material according to the item <1> or <2>, comprising a non-conjugated polymer.
<4> The thermoelectric conversion material according to any one of the items <1> to <3>, wherein the conjugated polymer has a repeating unit represented by the following formula (1):

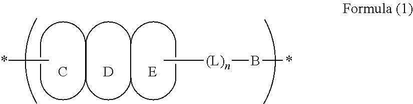

wherein in the formula (1), C and E each independently represent an aromatic hydrocarbon ring structure or an aromatic heterocyclic structure; D represents a hydrocarbon ring structure or a heterocyclic structure; the rings of C, D and E may each have a substituent; L represents —CH═CH—, —C≡C—, or —N═N—; n represents 0 or 1; B represents a monocyclic aromatic hydrocarbon ring structure, a monocyclic aromatic heterocyclic structure, or a condensed bicyclic structure including the monocyclic structure; and symbol * represents a linking site of the repeating unit.

<5> The thermoelectric conversion material according to any one of the items <1> to <4>, wherein the conjugated polymer has a repeating unit represented by the following formula (2):

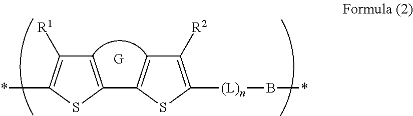

wherein in the formula (2), G represents a hydrocarbon ring structure or a heterocyclic structure; the ring G may have a substituent; R¹ and R² each independently represent a hydrogen atom or a substituent; and L represents —CH═CH—, —C≡C—, or —N═N—; n represents 0 or 1; B represents a monocyclic aromatic hydrocarbon ring structure, a monocyclic aromatic heterocyclic structure, or a condensed bicyclic structure including the monocyclic structure; and symbol * represents a linking site of the repeating unit.

<6> The thermoelectric conversion material according to any one of the items <1> to <4>, wherein the conjugated polymer has a repeating unit represented by the following formula (3):

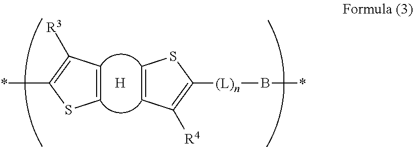

wherein in the formula (3), H represents a hydrocarbon ring structure or a heterocyclic structure; the ring H may have a substituent; R³ and R⁴ each independently represent a hydrogen atom or a substituent; and L represents —CH═CH—, —C≡C—, or —N═N—; n represents 0 or 1; B represents a monocyclic aromatic hydrocarbon ring structure, a monocyclic aromatic heterocyclic structure, or a condensed bicyclic structure including the monocyclic structure; and symbol * represents a linking site of the repeating unit.

<7> The thermoelectric conversion material according to any one of the items <4> to <6>, wherein in the formula (1), (2) or (3), the central ring of the condensed tricyclic structure is substituted with a linear or branched alkyl group.
<8> The thermoelectric conversion material according to any one of the items <4> to <7>, B represents a thiophene ring structure, a benzene ring structure, or a condensed bicyclic structure including the thiophene or benzene ring structure.
<9> The thermoelectric conversion material according to any one of the items <1> to <8>, wherein the molar ratio of the repeating units (A) and (B) in the conjugated polymer is 1:1.
<10> The thermoelectric conversion material according to any one of the items <3> to <9>, wherein the non-conjugated polymer is a polymeric compound formed by polymerizing a compound selected from the group consisting of a vinyl compound, a (meth)acrylate compound, a carbonate compound, an ester compound, an amide compound, an imide compound, and a siloxane compound.
<11> The thermoelectric conversion material according to any one of the items <1> to <10>, comprising a solvent, wherein the thermoelectric conversion material is formed by dispersing the carbon nanotubes in the solvent.
<12> The thermoelectric conversion material according to any one of the items <1> to <11>, comprising a dopant.
<13> The thermoelectric conversion material according to any one of the items <1> to <12>, comprising a thermal excitation assist agent.
<14> The thermoelectric conversion material according to the item <12>, wherein the dopant is an onium salt compound.
<15> The thermoelectric conversion material according to any one of the items <1> to <14>, wherein the moisture content of the thermoelectric conversion material is from 0.01% by mass to 15% by mass.
<16> A thermoelectric conversion element, using the thermoelectric conversion material according to any one of the items <1> to <15> in a thermoelectric conversion layer.
<17> The thermoelectric conversion element according to the item <16>, comprising two or more thermoelectric conversion layers, wherein at least one layer of the thermoelectric conversion layers contains the thermoelectric conversion material according to any one of the items <1> to <15>.
<18> The thermoelectric conversion element according to the item <17>, wherein among the two or more thermoelectric conversion layers, adjacent thermoelectric conversion layers contain conjugated polymers that are different from each other.
<19> The thermoelectric conversion element according to any one of the items <16> to <18>, comprising a substrate and the thermoelectric conversion layer provided on the substrate.
<20> The thermoelectric conversion element according to any one of the items <16> to <19>, further comprising electrodes.
<21> An article for thermoelectric power generation, using the thermoelectric conversion element according to any one of the items <16> to <20>.
<22> A carbon nanotube dispersion, comprising a carbon nanotube, a conjugated polymer, and a solvent,

wherein the carbon nanotubes are dispersed in the solvent, and

wherein the conjugated polymer at least has, as a repeating unit having a conjugated system,

(A) a condensed polycyclic structure in which three or more rings selected from hydrocarbon rings and heterocycles are condensed, and

(B) a monocyclic aromatic hydrocarbon ring structure, a monocyclic aromatic heterocyclic structure, or a condensed ring structure including the monocyclic structure.

In the present invention, the term “(meth)acrylate” means both or either of acrylate and methacrylate.

In the present invention, a numerical value range indicated using “to” means a range including the numerical values described before and after “to” as the lower limit and the upper limit.

In the present invention, when a substituent is described as an xxx group, the xxx group may have an arbitrary substituent. Also, when there are a number of groups represented by the same reference symbol, the groups may be identical with or different from each other.

### Effects of the Invention

The thermoelectric conversion material of the present invention exhibits excellent thermoelectric conversion performance, and can be suitably used in thermoelectric conversion elements or various articles for thermoelectric power generation. Furthermore, the thermoelectric conversion material of the present invention has satisfactory dispersibility of carbon nanotubes, and has excellent coating property and film-forming property.

Other and further features and advantages of the invention will appear more fully from the following description, appropriately referring to the accompanying drawings.

### BRIEF DESCRIPTION OF THE DRAWINGS

FIG. 1 is a diagram schematically showing one example of a thermoelectric conversion element of the present invention. An arrow in FIG. 1 shows a direction of temperature difference to be imparted during using the element.

FIG. 2 is a diagram schematically showing one example of a thermoelectric conversion element of the present invention. An arrow in FIG. 2 shows a direction of temperature difference to be imparted during using the element.

FIG. 3 is a diagram schematically showing one example of a thermoelectric conversion element of the present invention. An arrow in FIG. 3 shows a direction of temperature difference to be imparted during using the element.

FIG. 4 is a diagram schematically showing one example of a thermoelectric conversion element of the present invention. An arrow in FIG. 4 shows a direction of temperature difference to be imparted during using the element.

### MODE FOR CARRYING OUT THE INVENTION

The thermoelectric conversion material of the present invention contains a carbon nanotube and a conjugated polymer having particular repeating units.

The performance of a thermoelectric conversion material or a thermoelectric conversion element can be measured using a thermoelectric figure of merit ZT represented by the following formula (A).

Figure of merit ZT=S²σT/κ (A)

S (V/K): Thermopower (Seebeck coefficient)

σ (S/m): Electrical conductivity

κ (W/mK): Thermal conductivity

T (K): Absolute temperature

As is clear from the above formula (A), for enhancement of the thermoelectric conversion performance, it is required to increase the thermopower and the electrical conductivity, and to decrease the thermal conductivity. As such, the thermoelectric conversion performance is largely affected by factors other than the electrical conductivity. Therefore, even for a material which is generally considered to have high electrical conductivity, it is still unknown whether the material would function effectively as a thermoelectric conversion material in actual applications.

Furthermore, a thermoelectric conversion element works under the condition of keeping a temperature difference between the both ends of a thermoelectric conversion layer, and it is necessary to form a thermoelectric conversion layer by forming a thermoelectric conversion material into a shape having a certain thickness. Therefore, a thermoelectric conversion material is required to have satisfactory coating property or film-forming property.

As demonstrated in the Examples that will be described below, the thermoelectric conversion material of the present invention has a thermoelectric conversion performance sufficiently high to be used as a thermoelectric conversion material, and also has satisfactory dispersibility of carbon nanotubes and excellent coating property or film-forming property, so that the thermoelectric conversion material is suitable to be molded and processed into a thermoelectric conversion layer.

Hereinafter, the various components of the thermoelectric conversion material of the present invention will be explained.

### [Carbon Nanotube]

Carbon nanotubes (hereinafter, referred to as CNT) include a single-walled CNT in which one sheet of carbon film (graphene sheet) is cylindrically wound, a double-walled CNT in which two graphene sheets are concentrically wound, and a multi-walled CNT in which a plurality of graphene sheets are concentrically wound. In the present invention, the single-walled CNT, the double-walled CNT, and the multi-walled CNT may be used alone, or in combination with two or more kinds. A single-walled CNT and a double-walled CNT have excellent properties in the electrical conductivity and the semiconductor characteristics, and therefore a single-walled CNT and a double-walled CNT are preferably used, and a single-walled CNT is more preferably used.

The single-walled CNT may be used in the form of a semiconductive one or a metallic one, or both in combination with the semiconductive one and the metallic one. Moreover, the CNT may include a metal therein, or one including a molecule of fullerene or the like therein may also be used. In addition to the CNT, the thermoelectric conversion material of the present invention may contain nanocarbon materials such as a carbon nanohorn, a carbon nanocoil, and carbon nanobeads.

The CNT can be produced by an arc discharge process, a chemical vapor deposition process (hereinafter, referred to as a CVD process), a laser ablation process, or the like. The CNT used in the present invention may be obtained by any method, but preferably by the arc discharge process and the CVD process.

Upon producing the CNT, fullerene, graphite, or amorphous carbon is simultaneously formed as a by-product, and a catalyst metal such as nickel, iron, cobalt, and yttrium also remains. In order to remove these impurities, purification is preferably performed. A method of purification of the CNT is not particularly limited, but acid treatment by nitric acid, sulfuric acid, or the like, or ultrasonication is effective in removal of the impurities. In addition thereto, separation and removal using a filter is also preferably performed from a viewpoint of an improvement of purity.

After purification, the CNT obtained can also be directly used. Moreover, the CNT is generally produced in the form of strings, and therefore may be cut into a desired length according to a use. The CNT can be cut in the form of short fibers by acid treatment by nitric acid or sulfuric acid, ultrasonication, a freeze mill process, or the like. Moreover, in addition thereto, separation using the filter is also preferred from a viewpoint of an improvement of purity.

In the present invention, not only a cut CNT, but also a CNT previously prepared in the form of short fibers can be used. Such a CNT in the form of short fibers can be obtained, for example, by forming on a substrate a catalyst metal such as iron and cobalt, and according to the CVD method, allowing on the surface thereof vapor deposition of the CNT by thermally decomposing a carbon compound at 700 to 900° C., thereby obtaining the CNT in the shape of alignment on a substrate surface in a vertical direction. The thus prepared CNT in the form of short fibers can be taken out from the substrate by a method of stripping off the CNT, or the like. Moreover, the CNT in the form of short fibers can also be obtained by supporting a catalyst metal on a porous support such as porous silicon or on an anodized film of alumina to allow on a surface thereof vapor deposition of a CNT according to the CVD process. The CNT in the form of aligned short fibers can also be prepared according to a method in which a molecule such as iron phthalocyanine containing a catalyst metal in the molecule is used as a raw material, and a CNT is prepared on a substrate by performing CVD in a gas flow of argon/hydrogen. Furthermore, the CNT in the form of aligned short fibers can also be obtained on a SiC single crystal surface according to an epitaxial growth process.

A mean length of the CNT used in the present invention is not particularly limited, but from viewpoints of ease of production, film-forming property, electrical conductivity, or the like, the mean length of the CNT is preferably 0.01 μm or more to 1,000 μm or less, and more preferably 0.1 μm or more to 100 μm or less.

A diameter of the CNT used in the present invention is not particularly limited, but from viewpoints of durability, transparency, film-forming property, electrical conductivity, or the like, the diameter is preferably 0.4 nm or more to 100 nm or less, more preferably 50 nm or less, and further preferably 15 nm or less.

The content of CNT in the thermoelectric conversion material is preferably 2 to 60% by mass, more preferably 5 to 55% by mass, and particularly preferably 10 to 50% by mass, in the total solid content.

[Conjugated polymer]

A conjugated polymer is a polymeric compound having a conjugated system molecular structure. The conjugated system of the polymer may be a system in which multiple bonds and single bonds are alternately arranged on the main chain of a polymer, and may also be a system in which unshared electron pairs, radicals and the like constitute a portion of the conjugated system. According to the present invention, it is preferable that the conjugated polymer preferably have electrical conductivity from the viewpoint of the thermoelectric conversion efficiency.

The conjugated polymer used in the thermoelectric conversion material of the present invention has at least two kinds of structures, namely, a repeating unit (A) a condensed polycyclic structure in which three or more rings selected from hydrocarbon rings and heterocycles are condensed, and a repeating unit (B) a monocyclic aromatic hydrocarbon ring structure, a monocyclic aromatic heterocyclic structure, or a condensed ring structure including the monocyclic structure.

### Repeating Unit (A)

The repeating unit (A) is a condensed polycyclic structure in which three or more hydrocarbon rings, three or more heterocycles, or three or more hydrocarbon rings and heterocycles are condensed, and the repeating unit (A) includes a conjugated structure. The repeating unit (A) may be such that a polymer formed by linking this repeating unit has a molecular structure with contiguous conjugated systems. The repeating unit (A) includes a polycyclic structure formed by condensing aromatic hydrocarbon rings or heterocycles, as well as a condensed polycyclic structure such as a fluorene structure or a carbazole structure.

The hydrocarbon rings that constitute the repeating unit (A) include aromatic hydrocarbon rings and hydrocarbon rings other than aromatic rings, and are preferably 5-membered rings or 6-membered rings. Specific examples include aromatic hydrocarbon rings such as a benzene ring, a benzoquinone ring and a cyclopentadienyl anion; and aliphatic hydrocarbon rings such as a cyclopentadiene ring and a cyclopentane ring.

The heterocycles that constitute the repeating unit (A) include aromatic heterocycles and heterocycles other than aromatic rings, and are preferably 5-membered rings or 6-membered rings. Examples of heteroatoms include a nitrogen atom, a sulfur atom, an oxygen atom, a silicon atom, a phosphorus atom, a selenium atom, and a tellurium atom. Specific examples of the heterocycles include aromatic heterocycles such as a pyrrole ring, a thiophene ring, a furan ring, a selenophene ring, a tellurophene ring, an imidazole ring, a pyrazole ring, an oxazole ring, an isoxazole ring, a thiazole ring, an isothiazole ring, a pyridine ring, a pyridon-2-one ring, a pyrimidine ring, a pyridazine ring, a pyrazine ring, a triazine ring, a selenopyran ring, and a telluropyran ring; and aliphatic heterocycles such as a pyrrolidine ring, a silole ring, a perhydrosilole ring, a piperidine ring, a piperazine ring, and a morpholine ring.

These hydrocarbon rings or heterocycles may be in a neutral state, or may be in the form of cations such as onium salts.

The condensed ring of the repeating unit (A) may have a substituent. Examples of the substituent include a linear, branched or cyclic alkyl group, an alkoxy group, an alkyloxycarbonyl group, an alkylthio group, an alkoxyalkyleneoxy group, an alkoxyalkyleneoxyalkyl group, a crown ether group, an aryl group, a fluoroalkyl group, and a dialkylamino group. The number of carbon atoms of the alkyl moiety in the substituent is preferably 1 to 14, and more preferably 4 to 10. These substituents may be further substituted with similar substituents. When the condensed ring has plural substituents, the substituents may be bonded to each other and form a ring structure. Furthermore, the ends of each condensed ring structure or the aforementioned substituents may further have hydrophilic groups such as a carboxylic acid group, a sulfonic acid group, a hydroxyl group, and a phosphoric acid group.

It is preferable that the condensed ring skeleton of the repeating unit (A) include at least one heteroatom. Examples of the heteroatom include a nitrogen atom, a sulfur atom, an oxygen atom, a silicon atom, a phosphorus atom, a selenium atom, and a tellurium atom, and it is preferable that one kind or two or more kinds of these be contained. Further, it is more preferable that at least a sulfur atom is contained.

Furthermore, the condensed ring of the repeating unit (A) is preferably substituted with at least a linear or branched alkyl group, and is more preferably substituted with a linear or branched alkyl group having 1 to 14 carbon atoms (more preferably 4 to 10 carbon atoms).

The conjugated polymer used in the present invention may be composed of a single kind of the repeating unit (A), or may be composed of two or more kinds of the repeating unit (A) in combination.

Specific examples of the condensed ring structure of the repeating unit (A) will be described below, but the present invention is not intended to be limited to these. Meanwhile, in the following specific examples, symbol * represents a linking site of the repeating unit.

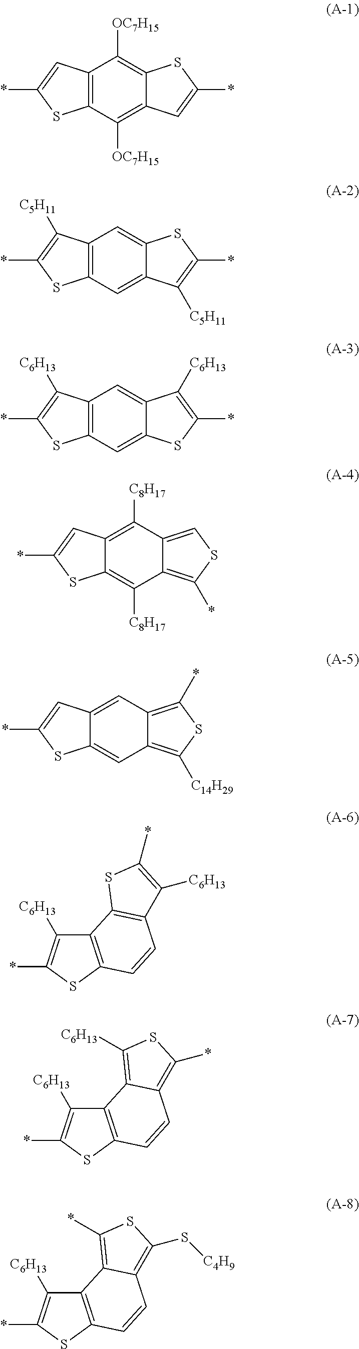

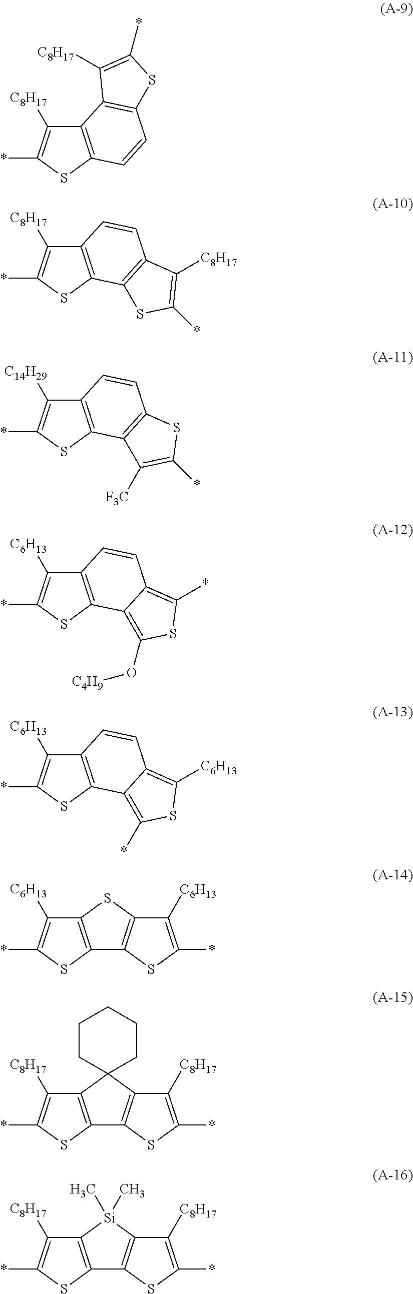

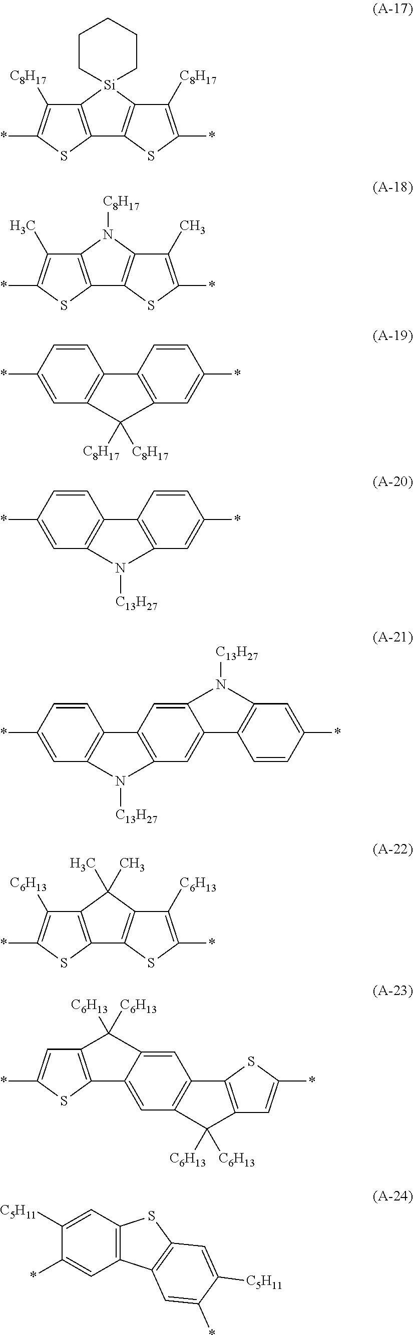

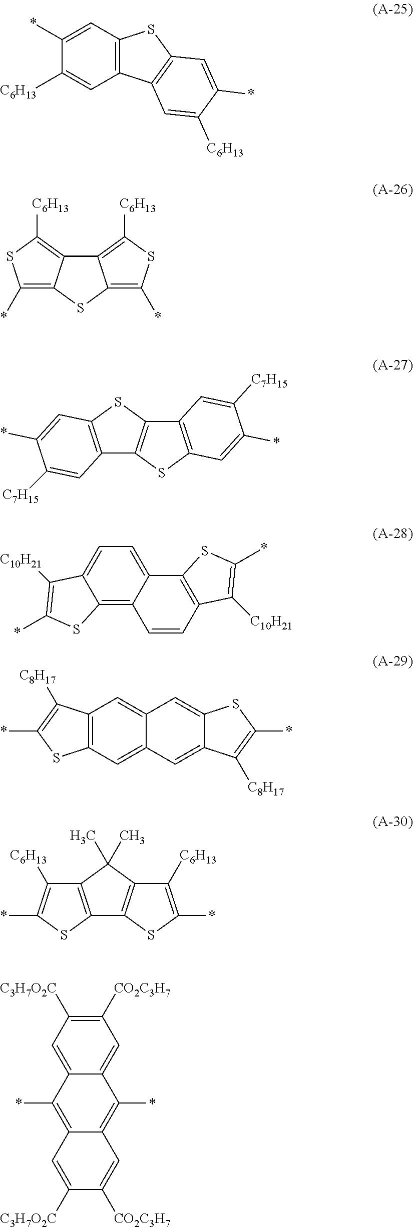

### Repeating Unit (B)

The repeating unit (B) is a monocyclic aromatic hydrocarbon ring structure, a monocyclic aromatic heterocyclic structure, or a condensed ring structure including the monocyclic structure. The repeating unit (B) is preferably a monocyclic aromatic hydrocarbon ring structure, a monocyclic aromatic heterocyclic structure, or a condensed bicyclic structure including the monocyclic structure. When the repeating unit (B) adopts the condensed ring structure, a structure in which the two linking sites to the polymer backbone are on the same aromatic hydrocarbon ring or aromatic heterocycle in the condensed ring, is preferred.

The aromatic hydrocarbon ring that constitutes the repeating unit (B) is preferably a 5-membered ring or a 6-membered ring. Specific examples include a benzene ring and a cyclopentadienyl anion.

The aromatic heterocycle that constitutes the repeating unit (B) is preferably a 5-membered ring or a 6-membered ring. Examples of heteroatoms include a nitrogen atom, a sulfur atom, an oxygen atom, a silicon atom, a phosphorus atom, a selenium atom, and a tellurium atom. Specific examples include a thiophene ring, a pyrrole ring, a furan ring, an imidazole ring, a pyrazole ring, an oxazole ring, an isoxazole ring, a thiazole ring, an isothiazole ring, a silole ring, a selenophene ring, a tellurophene ring, a pyridine ring, a pyridon-2-one ring, a pyrimidine ring, a pyridazine ring, a pyrazine ring, a triazine ring, a selenopyran ring, and a telluropyran ring.

When the repeating unit (B) is the condensed ring structure, a ring that forms the condensed structure with the aromatic hydrocarbon ring or the aromatic heterocycle may be a hydrocarbon ring or a heterocycle, and these rings may be aromatic rings, or may be other rings. Specific examples include a benzene ring, a cyclopentadiene ring, a thiophene ring, a pyrrole ring, a furan ring, an imidazole ring, a pyrazole ring, an oxazole ring, an isoxazole ring, a thiazole ring, an isothiazole ring, a silole ring, a selenophene ring, a tellurophene ring, a benzoquinone ring, a pyridine ring, a pyridon-2-one ring, a pyrimidine ring, a pyridazine ring, a pyrazine ring, a triazine ring, a selenopyran ring, a telluropyran ring, a pyrrolidine-2,5-dione ring, and a thiadiazole ring.

These rings that constitute the repeating unit (B) may be in a neutral state, or may be in the form of cations such as onium salts.

The repeating unit (B) is preferably a thiophene ring structure or a condensed bicyclic structure including a thiophene ring structure, or a benzene ring structure or a condensed bicyclic structure including a benzene ring structure.

The ring structure of the repeating unit (B) may have a substituent. Examples of the substituent include a linear, branched or cyclic alkyl group, an alkoxy group, an alkyloxycarbonyl group, an alkylthio group, an alkoxyalkyleneoxy group, an alkoxyalkyleneoxyalkyl group, a crown ether group, an aryl group, a fluoroalkyl group, a dialkylamino group, a diarylamino group, and a halogen atom (preferably a fluorine atom). The number of carbon atoms of the alkyl moiety in the substituent is preferably 1 to 14, and more preferably 4 to 10. These substituents may be further substituted with similar substituents. When the repeating unit (B) has plural substituents, these substituents may be bonded to each other and form a ring structure. Furthermore, the ends of each condensed ring structure or the aforementioned substituents may further have hydrophilic groups such as a carboxylic acid group, a sulfonic acid group, a hydroxyl group, and a phosphoric acid group.

Furthermore, the ring structure of the repeating unit (B) is preferably substituted with at least a linear or branched alkyl group, and is more preferably substituted with a linear or branched alkyl group having 1 to 14 carbon atoms (more preferably 4 to 10 carbon atoms).

The conjugated polymer used in the present invention may be composed of a single kind of the repeating unit (B), or may be composed of two or more kinds of the repeating unit (B) in combination.

Specific examples of the ring structure of the repeating unit (B) will be described below, but the present invention is not intended to be limited to these. Meanwhile, in the following specific examples, symbol * represents a linking site of the repeating unit.

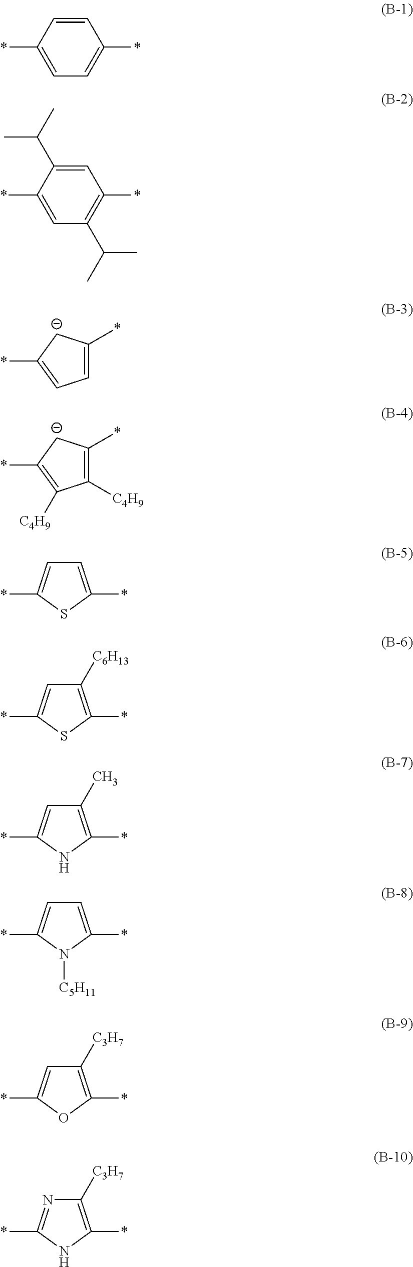

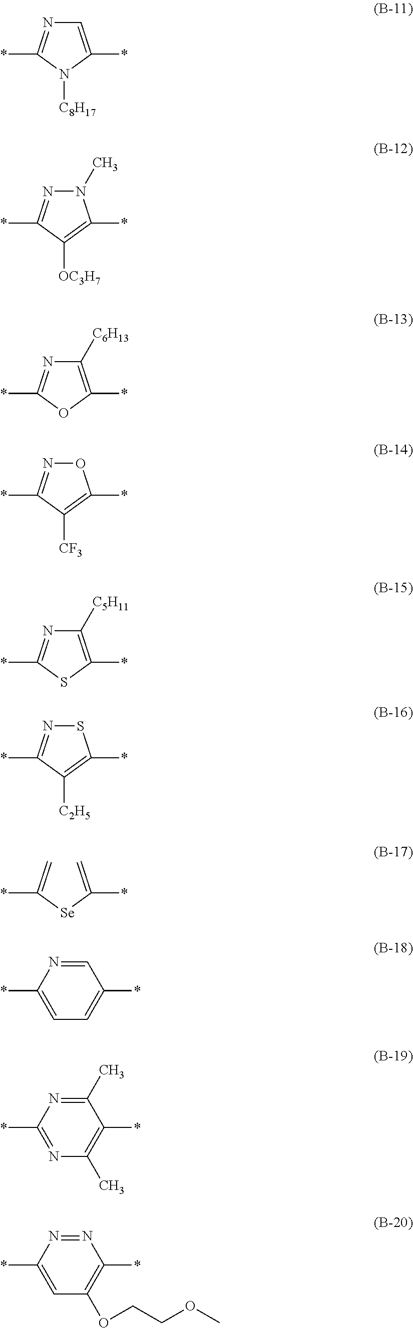

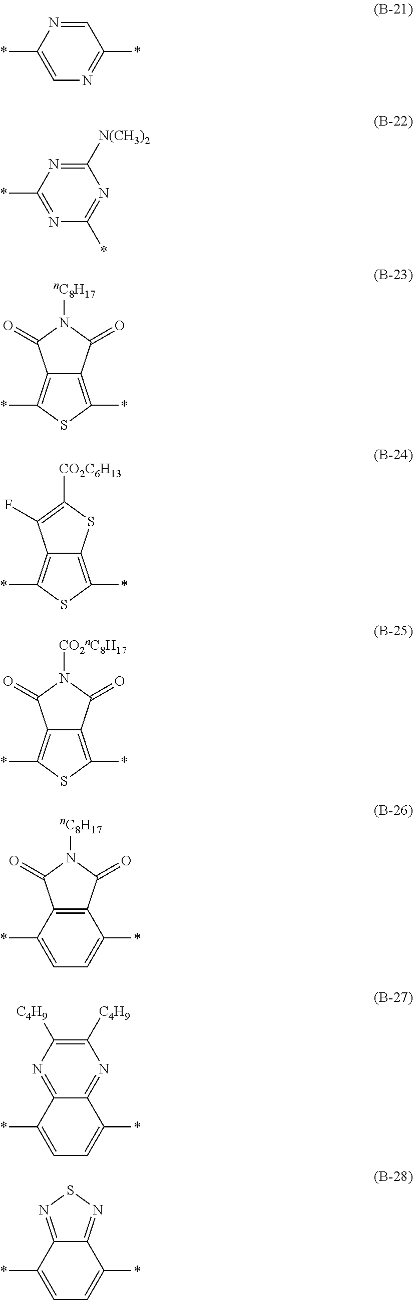

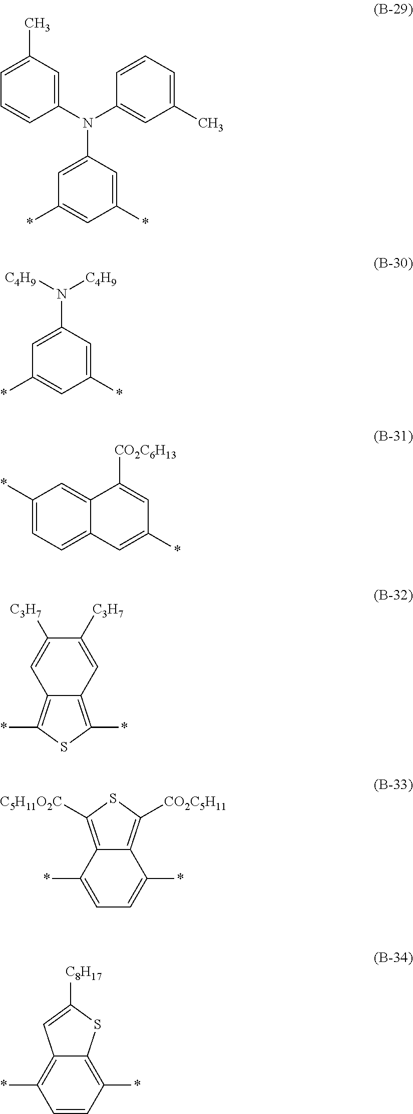

The conjugated polymer used in the present invention preferably has, as a repeating unit including both the repeating unit (A) and the repeating unit (B), a repeating unit represented by the following formula (1):

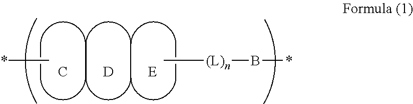

In the formula (1), the condensed tricyclic ring composed of C, D, and E corresponds to the repeating unit (A), and C and E each independently represent an aromatic hydrocarbon ring structure or an aromatic heterocyclic structure, while D represents a hydrocarbon ring structure or a heterocyclic structure. When each of the rings C, D and E adopts the heterocyclic structure, examples of heteroatoms include a nitrogen atom, a sulfur atom, an oxygen atom, a silicon atom, a phosphorus atom, a selenium atom, and a tellurium atom. Each of the rings C, D and E is preferably a 5-membered ring or a 6-membered ring. B corresponds to the repeating unit (B), and represents a monocyclic aromatic hydrocarbon ring structure, a monocyclic aromatic heterocyclic structure, or a condensed bicyclic ring structure including the monocyclic structure. B is preferably a 5-membered ring, a 6-membered ring, or a condensed bicyclic ring thereof.

Examples of the aromatic hydrocarbon ring that constitute the rings C and E include the aromatic hydrocarbon rings as shown in the specific examples of the hydrocarbon ring that constitutes the repeating unit (A) described above, and a preferred example is a benzene ring.

Examples of the aromatic heterocycle that constitutes the rings C and E include the aromatic heterocycles as shown in the specific examples of the heterocycle that constitutes the repeating unit (A) described above, and a preferred example is a thiophene ring.

Examples of the hydrocarbon ring that constitutes the ring D include the hydrocarbon rings listed for the examples of the hydrocarbon ring that constitutes the repeating unit (A) described above, and preferred examples include a benzene ring, a cyclopentadiene ring, and a cyclopentane ring.

Examples of the heterocycle that constitutes the ring D include the heterocycles listed for the examples of the heterocycle that constitutes the repeating unit (A) described above, and preferred examples include a pyrrole ring, a silole ring, a pyrrolidine ring, and a perhydrosilole ring.

Each of the rings C, D and E may have a substituent. Particularly, it is preferable that the ring D have a substituent. Examples of the substituent include the substituents listed as the examples of the substituent that the condensed ring of the repeating unit (A) may carry, and a preferred example is a linear or branched alkyl group, and a more preferred example is a linear or branched alkyl group having 1 to 14 carbon atoms (more preferably 4 to 10 carbon atoms).

The condensed ring composed of C, D and E preferably includes at least one heteroatom. Examples of the heteroatom include a nitrogen atom, a sulfur atom, an oxygen atom, a silicon atom, a phosphorus atom, a selenium atom, and a tellurium atom. It is preferable that one kind or two or more kinds of these is contained, and it is more preferable that at least a sulfur atom is included.

B corresponds to the repeating unit (B) described above. Examples of the monocyclic aromatic hydrocarbon ring, the monocyclic aromatic heterocycle, and the condensed bicyclic ring including the monocyclic ring include the examples listed for the repeating unit (B) described above, and preferred ranges thereof are also the same.

B is more preferably a benzene ring or a thiophene ring as a monocyclic structure, and a condensed bicyclic ring including a benzene ring or a thiophene ring as a condensed bicyclic structure. Furthermore, preferred examples of the substituent that is carried by B include a linear or branched alkyl group, and an alkyloxycarbonyl group, and a more preferred example is a linear or branched alkyl group, and a further preferred example is a linear or branched alkyl group having 1 to 14 carbon atoms (more preferably 4 to 10 carbon atoms).

In the formula (1), L represents —CH═CH— (double bond), —C≡C— (triple bond), or —N═N— (azo bond), and n represents 0 or 1. n is preferably 0. Meanwhile, when n=0, the ring E and the ring B are linked by a single bond.

Symbol * represents a linking site of the repeating unit.

The repeating unit represented by the formula (1) is preferably a repeating unit represented by the following formula (2) or (3):

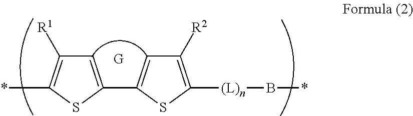

In the formula (2), G represents a hydrocarbon ring structure or a heterocyclic structure. When a heterocyclic structure is adopted, examples of heteroatoms include a nitrogen atom, a sulfur atom, an oxygen atom, a silicon atom, a phosphorus atom, a selenium atom, and a tellurium atom. G is preferably a 5-membered ring.

Examples of the hydrocarbon ring or heterocycle that constitutes the ring G include the examples listed for the hydrocarbon ring or heterocycle that constitutes the ring D of the formula (1), and preferred examples include a cyclopentadiene ring, a cyclopentane ring, a pyrrole ring, a silole ring, a pyrrolidine ring, and a perhydrosilole ring.

The ring G may have a substituent, and it is preferable that the ring G have a substituent. Examples of the substituent include the examples listed as the substituents that the ring D of the formula (1) may carry, and a preferred example is a linear or branched alkyl group, and more preferably a linear or branched alkyl group having 1 to 14 carbon atoms (more preferably 4 to 10 carbon atoms).

In the formula (2), R¹ and R² each independently represent a hydrogen atom or a substituent. Examples of the substituent include the examples listed as the substituents that the ring C or E of the formula (1) may carry. R¹ and R² are preferably hydrogen atoms.

In the formula (2), B has the same meaning as B in the formula (1), and a preferred range thereof is also the same.

Furthermore, in the formula (2), L and n respectively have the same meanings as L and n in the formula (1), and preferred ranges thereof are also the same.

Symbol * represents a linking site of the repeating unit.

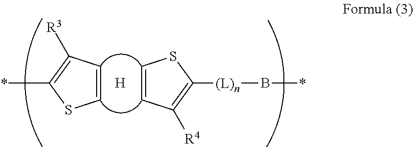

In the formula (3), H represents a hydrocarbon ring structure or a heterocyclic structure. When a heterocyclic structure is adopted, examples of heteroatoms include a nitrogen atom, a sulfur atom, an oxygen atom, a silicon atom, a phosphorus atom, a selenium atom, and a tellurium atom. H is preferably a 6-membered ring.

Examples of the hydrocarbon ring or heterocycle that constitutes the ring H include the examples listed for the hydrocarbon ring or heterocycle that constitutes the ring D of the formula (1), and preferred examples include a benzene ring.

The ring H may have a substituent, and it is preferable that the ring H have a substituent. Examples of the substituent include the examples listed as the substituents that the ring D of the formula (1) may carry, and a preferred example is a linear or branched alkyl group, and more preferably a linear or branched alkyl group having 1 to 14 carbon atoms (more preferably 4 to 10 carbon atoms).

In the formula (3), R³ and R⁴ each independently represent a hydrogen atom or a substituent. Examples of the substituent include the examples listed as the substituents that the ring C or E of the formula (1) may carry. R³ and R⁴ are preferably hydrogen atoms.

In the formula (3), B has the same meaning as B in the formula (1), and a preferred range thereof is also the same.

Furthermore, in the formula (3), L and n respectively have the same meanings as L and n in the formula (1), and preferred ranges thereof are also the same.

Symbol * represents a linking site of the repeating unit.

Specific examples of the repeating unit represented by the formulae (1) to (3) will be described below, but the present invention is not intended to be limited to these. Meanwhile, in the following specific examples, symbol * represents a linking site of the repeating unit.

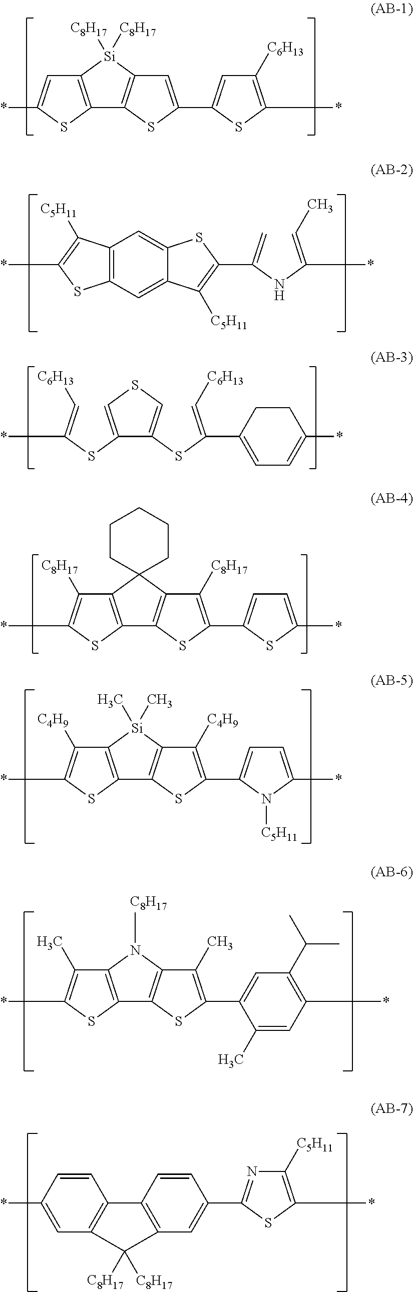

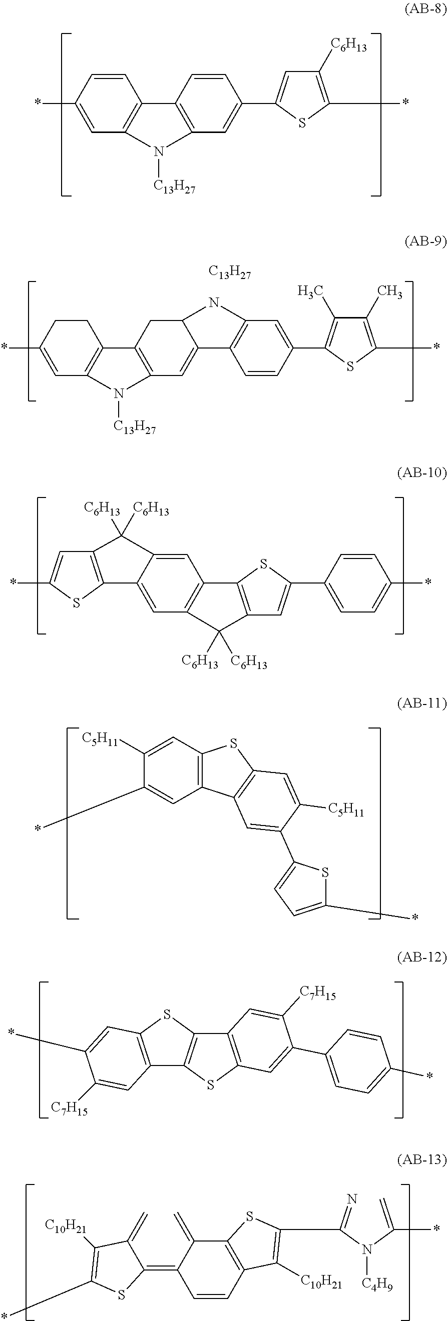

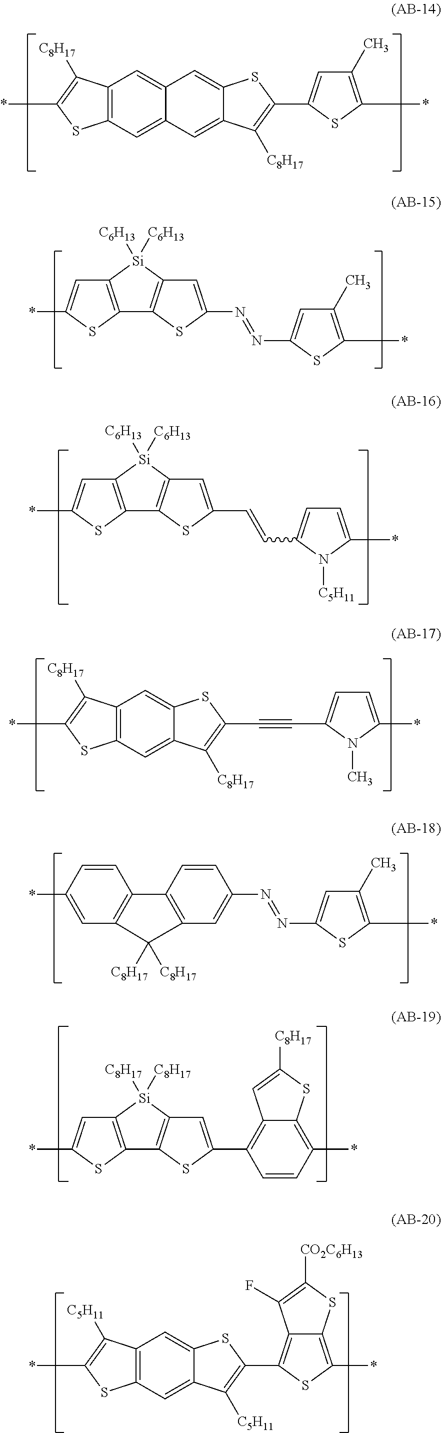

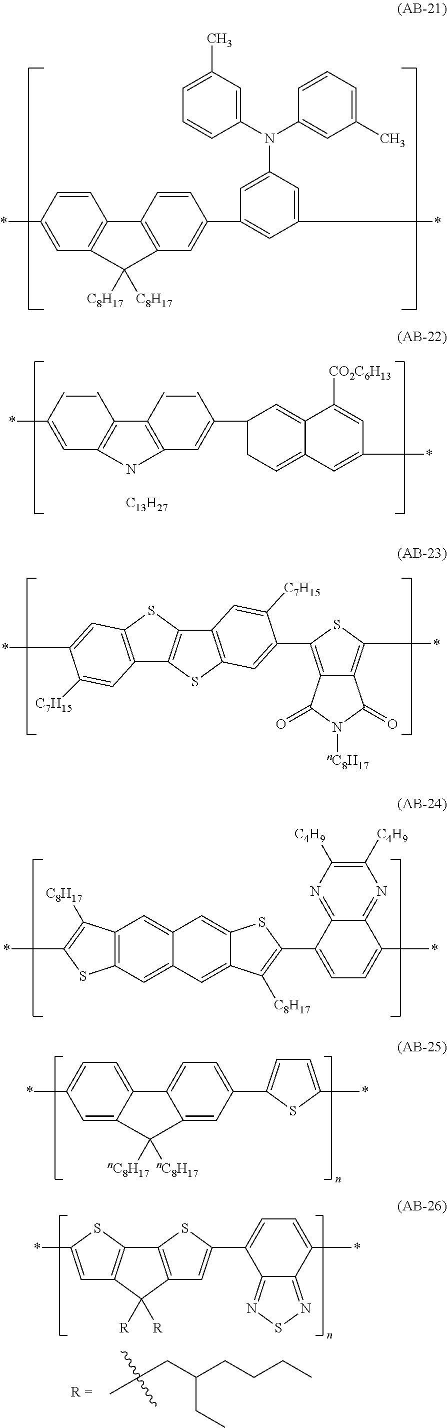

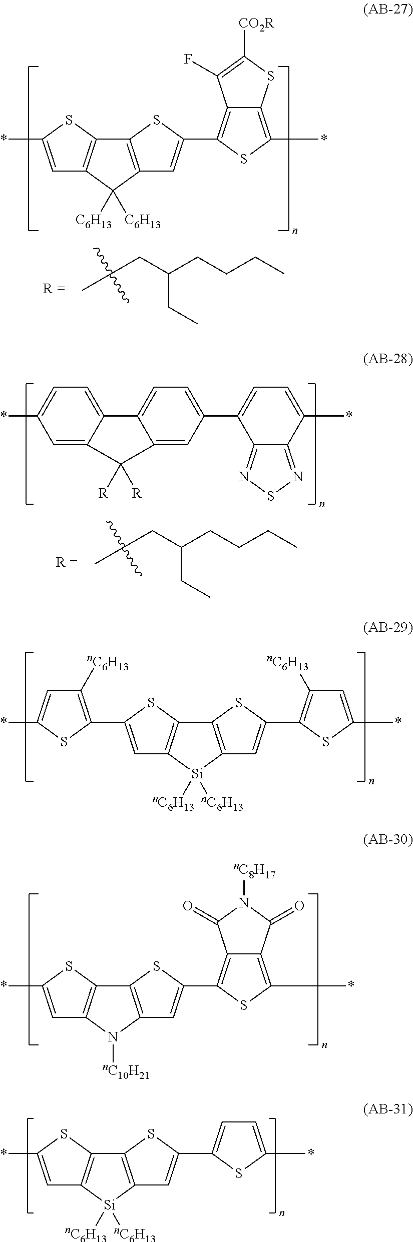

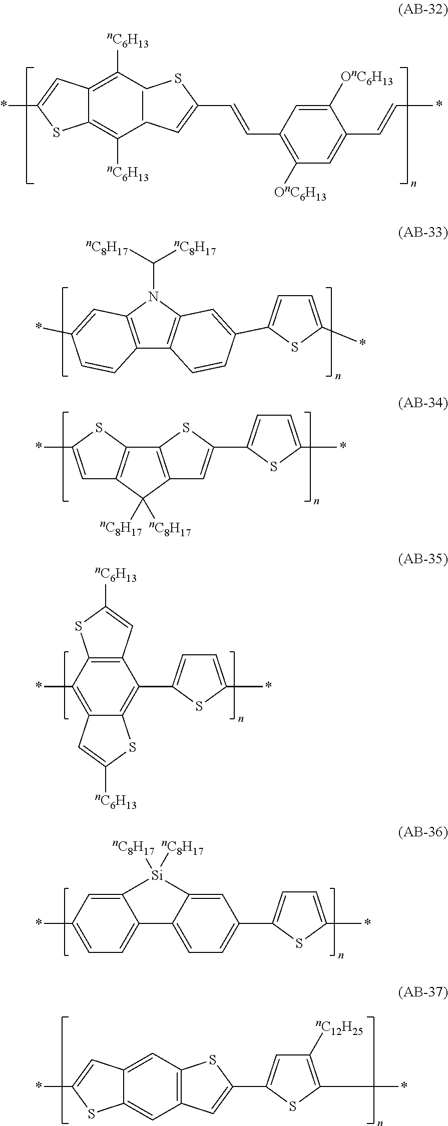

The conjugated polymer used in the present invention may be composed of a single kind of the repeating units represented by the formulae (1) to (3), or may be composed of two or more kinds thereof in combination.

The conjugated polymer used in the present invention may include another structure (including another repeating unit), in addition to the repeating units described above. The other structure is preferably a conjugated structure, and examples include structures derived from —CH═CH— (double bond), —C≡C— (triple bond), —N═N— (azo bond), a thiophene-based compound, a pyrrole-based compound, an aniline-based compound, an acetylene-based compound, a p-phenylene-based compound, a p-phenylene-vinylene-based compound, a p-phenylene-ethynylene-based compound, a p-fluorenylene-vinylene-based compound, a polyacene-based compound, a polyphenanthrene-based compound, a metal phthalocyanine-based compound, a p-xylene-based compound, a vinylene sulfide-based compound, an m-phenylene-based compound, a naphthalene-vinylene-based compound, a p-phenylene oxide-based compound, a phenylene sulfide-based compound, a furan-based compound, a selenophene-based compound, an azo-based compound, a metal complex-based compound, a benzothiadiazole-based compound, a carbazole-based compound, a polysilane-based compound, a benzimidazole-based compound, an imidazole-based compound, a pyrimidine-based compound; derivatives thereof; or condensed compounds thereof. The other structures may be included in the conjugated polymer as a repeating unit.

When the polymer has a plurality of kinds of repeating units, the polymer may be a block copolymer, a random copolymer, or a graft polymer.

The molecular weight of the conjugated polymer is not particularly limited, and a polymer having a high molecular weight as well as an oligomer having a molecular weight less than that (for example, a weight average molecular weight of about 1,000 to 10,000) may be used.

In order to increase electrical conductivity of the thermoelectric conversion material, intramolecular carrier transfer through a long conjugated chain of the conjugated polymer, and intermolecular carrier hopping are required. Therefore, a conjugated polymer having a molecular weight that is high to a certain extent is preferred. From this point of view, the molecular weight of the conjugated polymer is, as a weight average molecular weight, preferably 5,000 or more, more preferably 7,000 to 300,000, and further preferably 8,000 to 100,000. The weight average molecular weight can be measured by gel permeation chromatography (GPC).

These conjugated polymers can be produced by polymerizing monomers having the structure of repeating unit described above as a raw material by a conventional oxidation polymerization method, or a coupling polymerization method.

The content of the conjugated polymer in the thermoelectric conversion material of the present invention is preferably 3% to 80% by mass, more preferably 5% to 60% by mass, and particularly preferably 10% to 50% by mass, relative to the total solid content of the material.

Furthermore, when the thermoelectric conversion material includes a non-conjugated polymer that will be described below, the content of the conjugated polymer in the thermoelectric conversion material is preferably 3% to 70% by mass, more preferably 5% to 60% by mass, and particularly preferably 10% to 50% by mass, relative to the total solid content of the material.

From the viewpoints of enhancing CNT dispersibility and film-forming property, the conjugated polymer used in the thermoelectric conversion material of the present invention is preferably such that the molar ratio between the repeating unit (A) and the repeating unit (B) in the conjugated polymer is 1:1. Meanwhile, a number of repetition of each repeating unit of 1 is considered as 1 mole.

The conjugated polymer used in the thermoelectric conversion material of the present invention has two kinds of repeating units (A) and (B) as essential constituent units, and can thereby realize dispersibility of CNT, solubility of the conjugated polymer, and film-forming property of the thermoelectric conversion material. The repeating unit (A) is a condensed ring structure having three or more rings and has π-conjugated system with a high planarity. This structure allows enhancing a π-πinteraction with CNT surfaces. Therefore, as the proportion of the repeating unit (A) is larger, the dispersibility of CNT is increased. On the other hand, when the proportion of the repeating unit (A) is increased, rigidity of the polymer main chain also increases. If rigidity of the polymer main chain is high, solubility of the conjugated polymer is decreased, and film-forming property is also deteriorated. Therefore, it is preferable to control rigidity of the main chain to a certain extent. Thus, in order to enhance flexibility of the polymer main chain, the repeating unit (B) having relatively lower planarity is used together.

In order to mitigate rigidity of the polymer main chain by means of the repeating unit (B) and to obtain satisfactory solubility of the conjugated polymer and satisfactory film-forming property of the material while maintaining the CNT dispersibility caused by the repeating unit (A), it is preferable to adjust the molar ratio between the repeating unit (A) and the repeating unit (B) to 1:1.

### [Non-Conjugated Polymer]

The thermoelectric conversion material of the present invention preferably contains a non-conjugated polymer. The non-conjugated polymer is a polymeric compound which does not have a conjugated molecular structure.

In the present invention, the kind of the non-conjugated polymer is not particularly limited, and any non-conjugated polymer that is conventionally known can be used. Preferably, a polymeric compound formed by polymerizing a compound selected from the group consisting of a vinyl compound, a (meth)acrylate compound, a carbonate compound, an ester compound, an amide compound, an imide compound and a siloxane compound is used.

Specific examples of the vinyl compound include vinylarylamines such as styrene, vinylpyrrolidone, vinylcarbazole, vinylpyridine, vinylnaphthalene, vinylphenol, vinyl acetate, styrenesulfonic acid, vinyl alcohol, and vinyltriphenylamine; and vinyltrialkylamines such as vinyltributylamine.

Specific examples of the (meth)acrylate compound include acrylate-based monomers including alkyl group-containing hydrophobic acrylates such as methyl acrylate, ethyl acrylate, propyl acrylate, and butyl acrylate; hydroxyl group-containing acrylates such as 2-hydroxyethyl acrylate, 1-hydroxyethyl acrylate, 2-hydroxypropyl acrylate, 3-hydroxypropyl acrylate, 1-hydroxypropyl acrylate, 4-hydroxybutyl acrylate, 3-hydroxybutyl acrylate, 2-hydroxybutyl acrylate, and 1-hydroxybutyl acrylate; and methacrylate-based monomers in which the acryloyl groups of these monomers are changed to methacryloyl groups.

Specific examples of the polymer formed by polymerizing a carbonate compound include general-purpose polycarbonates formed from bisphenol A and phosgene, IUPIZETA (trade name, manufactured by MITSUBISHI GAS CHEMICAL CO., INC.), and PANLITE (trade name, manufactured b TEIJIN LIMITED).

Specific examples of the ester compound include lactic acid. Furthermore, specific examples of the polymer formed by polymerizing an ester compound include VYLON (trade name, manufactured by TOYOBO CO., LTD.).

Specific examples of the polymer formed by polymerizing an amide compound include PA-100 (trade name, manufactured by T&K TOKA CO., LTD).

Specific examples of the polymer formed by polymerizing an imide compound include SOLPIT 6,6-PI (trade name, manufactured by Solpit Industries, Ltd.).

Specific examples of the siloxane compound include diphenylsiloxane and phenylmethylsiloxane.

The non-conjugated polymer may be a homopolymer, or may be a copolymer.

In the present invention, it is more preferable to use a polymer compound that is formed by polymerizing a vinyl compound, as the non-conjugated polymer.

It is preferable that the non-conjugated polymer be hydrophobic, and it is more preferable that the non-conjugated polymer do not have a hydrophilic group such as a sulfonic acid or a hydroxyl group in the molecule. Furthermore, a non-conjugated polymer having a solubility parameter (SP value) of 11 or less is preferred.

By incorporating a non-conjugated polymer together with the conjugated polymer into the thermoelectric conversion material, an enhancement of the thermoelectric conversion performance of the material can be promoted. The mechanism thereof include some points that are not clearly understood, but it is speculated to be because: (1) since a non-conjugated polymer has a broad band gap between the HOMO level and the LUMO level, the carrier concentration in the polymer can be maintained at an appropriately low level, so that the Seebeck coefficient can be retained at a higher level than a system that does not include a non-conjugated polymer; and further (2) transport routes of the carriers are formed as a result of the co-presence of the conjugated polymer and CNT, and a high electrical conductivity can be retained. That is, when three components of CNT, a non-conjugated polymer and a conjugated polymer are allowed to co-exist in the material, both the Seebeck coefficient and the electrical conductivity can be enhanced, and as a result, the thermoelectric conversion performance (ZT value) is significantly enhanced.

The content of the non-conjugated polymer in the thermoelectric conversion material is preferably 10 parts to 1500 parts by mass, more preferably 30 parts to 1200 parts by mass, and particularly preferably 80 parts to 1000 parts by mass, relative to 100 parts by mass of the conjugated polymer. When the content of the non-conjugated polymer is in the range described above, a decrease in the Seebeck coefficient and a decrease in the thermoelectric conversion performance (ZT value) caused by an increase in the carrier concentration are not observed, and deterioration of CNT dispersibility and a decrease in electrical conductivity and thermoelectric conversion performance caused by incorporation of a non-conjugated polymer are also not observed, which is therefore preferable.

### [Solvent]

The thermoelectric conversion material of the present invention preferably contains a solvent. The thermoelectric conversion material of the present invention is more preferably a CNT dispersion liquid in which CNT's are dispersed in a solvent.

The solvent may be any solvent capable of satisfactorily dispersing or dissolving the components. Water, an organic solvent, and mixed solvents thereof can be used. The solvent is preferably an organic solvent, and preferred examples include alcohols; halogen-based solvents such as chloroform; aprotic polar solvents such as DMF, NMP and DMSO; aromatic solvents such as chlorobenzene, dichlorobenzene, benzene, toluene, xylene, mesitylene, tetralin, tetramethylbenzene, and pyridine; ketone-based solvents such as cyclohexanone, acetone, and methyl ethyl ketone; and ether-based solvents such as diethyl ether, THF, t-butyl methyl ether, dimethoxyethane, and diglyme, and more preferred examples include halogen-based solvents such as chloroform, aprotic polar solvents such as DMF and NMP; aromatic solvents such as dichlorobenzene, xylene, tetralin, and tetramethylbenzene; and ether-based solvents such as THF.

Furthermore, it is preferable to have the solvent degassed in advance and to adjust the dissolved oxygen concentration in the solvent to 10 ppm or less. Examples of the method of degassing include a method of irradiating ultrasonic waves under reduced pressure; and a method of bubbling an inert gas such as argon.

Furthermore, it is preferable to have the solvent dehydrated in advance. It is preferable to adjust the amount of water in the solvent to 1,000 ppm or less, and more preferably to 100 ppm or less. Regarding the method of dehydration, known methods such as a method of using a molecular sieve, and distillation, can be used.

The amount of the solvent in the thermoelectric conversion material is preferably 90% to 99.99% by mass, more preferably 95% to 99.95% by mass, and further preferably 98% to 99.9% by mass, relative to the total amount of the thermoelectric conversion material.

As demonstrated in the Examples that will be described below, a composition including a conjugated polymer having the particular repeating unit described above together with a CNT and a solvent exhibits satisfactory CNT dispersibility. From this point of view, another embodiment of the present invention includes a carbon nanotube dispersion which contains the conjugated polymer described above, a carbon nanotube, and a solvent, and which is formed by dispersing the carbon nanotubes in the solvent. The dispersion has high dispersibility of carbon nanotubes, and can exhibit the high electrical conductivity intrinsic to carbon nanotubes. Therefore, the dispersion can be suitably used in various conductive materials including thermoelectric conversion materials.

### [Dopant]

The thermoelectric conversion material of the present invention may contain a dopant. The dopant is a compound that is doped into the conjugated polymer, and may be any compound capable of doping the conjugated polymer to have a positive charge (p-type doping) by protonizing the conjugated polymer or eliminating electrons from the π-conjugated system of the conjugated polymer. Specifically, an onium salt compound, an oxidizing agent, an acidic compound, an electron acceptor compound and the like as described below can be used.

### 1. Onium Salt Compound

The onium salt compound to be used as the dopant preferably includes a compound (an acid generator, acid precursor) that generates acid by providing energy such as irradiation of active energy rays (such as radiation and electromagnetic waves). Specific examples of such onium salt compounds include a sulfonium salt, an iodonium salt, an ammonium salt, a carbonium salt, and a phosphonium salt. Among these, a sulfonium salt, an iodonium salt, an ammonium salt, or a carbonium salt is preferred, a sulfonium salt, an iodonium salt, or a carbonium salt is more preferred, a sulfonium salt, an iodonium salt is particularly preferred. Specific examples of an anion part constituting such a salt include counter anions of strong acid.

Specific examples of the sulfonium salts include compounds represented by the following Formulae (I) and (II), specific examples of the iodonium salts include compounds represented by the following Formula (III), specific examples of the ammonium salts include compounds represented by the following Formula (IV), and specific examples of the carbonium salts include compounds represented by the following Formula (V), respectively, and such compounds are preferably used in the present invention.

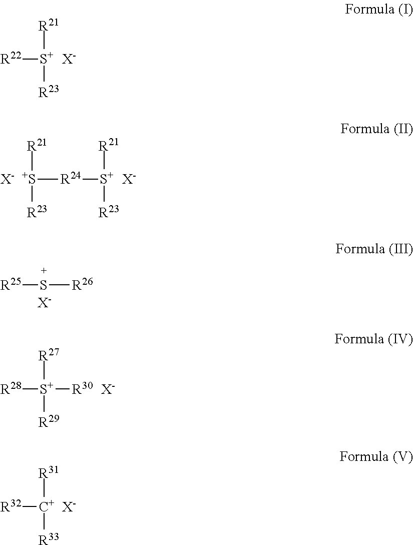

In Formulae (I) to (V), R²¹ to R²³, R²⁵ to R²⁶, and R³¹ to R³³ each independently represent an alkyl group, aralkyl group, aryl group, or aromatic heterocyclic group. R²⁷ to R³⁰ each independently represent a hydrogen atom, or alkyl group, aralkyl group, aryl group, aromatic heterocyclic group, alkoxy group, or aryloxy group. R²⁴ represents an alkylene group or arylene group. R²¹ to R³³ may be further substituted. X⁻ represents an anion of strong acid.

Any two groups of R²¹ to R²³ in Formula (I), R²¹ and R²³ in Formula (II), R²⁵ and R²⁶ in Formula (III), any two groups of R²⁷ to R³⁰ in Formula (IV), and any two groups of R³¹ to R³³ in Formula (V) may be bonded with each other to form an aliphatic ring, an aromatic ring, or a heterocyclic ring.

In R²¹ to R²³, or R²⁵ to R³³, the alkyl group includes a linear, branched or cyclic alkyl group. The linear or branched alkyl group is preferably an alkyl group having 1 to 20 carbon atoms, and specific examples thereof include a methyl group, an ethyl group, a propyl group, a n-butyl group, a sec-butyl group, a t-butyl group, a hexyl group, an octyl group, and a dodecyl group.

The cycloalkyl group is preferably an alkyl group having 3 to 20 carbon atoms, and specific examples thereof include a cyclopropyl group, a cyclopentyl group, a cyclohexyl group, a bicyclooctyl group, a norbornyl group, and an adamantyl group.

The aralkyl group is preferably an aralkyl group having 7 to 15 carbon atoms, and specific examples thereof include a benzyl group, and a phenetyl group.

The aryl group is preferably an aryl group having 6 to 20 carbon atoms, and specific examples thereof include a phenyl group, a naphthyl group, an anthranyl group, a phenanthryl group, and a pyrenyl group.

Specific examples of the aromatic heterocyclic groups include a pyridyl group, a pyrazol group, an imidazole group, a benzimidazole group, an indole group, a quinoline group, an isoquinoline group, a purine group, a pyrimidine group, an oxazole group, a thiazole group, and a thiazine group.

In R²⁷ to R³⁰, The alkoxy group is preferably a linear or branched alkoxy group having 1 to 20 carbon atoms, and specific examples thereof include a methoxy group, an ethoxy group, an iso-propoxy group, a butoxy group, and a hexyloxy group.

The aryloxy group is preferably an aryloxy group having 6 to 20 carbon atoms, and specific examples thereof include a phenoxy group and a naphthyloxy group.

In R²⁴, the alkylene group includes a linear, branched and cyclic alkylene group, and an alkylene group having 2 to 20 carbon atoms is preferred. Specific examples thereof include an ethylene group, a propylene group, a butylene group, and a hexylene group. The cyclic alkylene group is preferably a cyclic alkylene group having 3 to 20 carbon atoms, and specific examples thereof include a cyclopentyl group, a cyclohexylene group, a bicyclooctylene group, a norbornylene group, and an adamantylene group.

The arylene group is preferably an arylene group having 6 to 20 carbon atoms, and specific examples thereof include a phenylene group, a naphthylene group, and an anthranylene group.

When R²¹ to R³³ further have a substituent, specific examples of preferred substituents include an alkyl group having 1 to 4 carbon atoms, an alkoxy group having 1 to 4 carbon atoms, a halogen atom (a fluorine atom, a chlorine atom, or an iodine atom), an aryl group having 6 to 10 carbon atoms, an aryloxy group having 6 to 10 carbon atoms, an alkenyl group having 2 to 6 carbon atoms, a cyano group, a hydroxyl group, a carboxy group, an acyl group, an alkoxycarbonyl group, an alkylcarbonylalkyl group, an arylcarbonylalkyl group, a nitro group, an alkylsulfonyl group, a trifluoromethyl group, and —S—R⁴¹. In addition, R⁴¹ has the same meaning as R²¹.

X⁻ is preferably an anion of aryl sulfonic acid, an anion of perfluoroalkyl sulfonic acid, an anion of perhalogenated Lewis acid, an anion of perfluoroalkyl sulfonimide, an anion of perhalogenated acid, or an anion of alkyl or aryl borate. These anions may further have a substituent, and a specific example of the substituent includes a fluoro group.

Specific examples of the anions of aryl sulfonic acid include p-CH₃C₆H₄SO₃⁻, PhSO₃⁻, an anion of naphthalene sulfonic acid, an anion of naphthoquinone sulfonic acid, an anion of naphthalene disulfonic acid, and an anion of anthraquinone sulfonic acid.

Specific examples of the anions of perfluoroalkyl sulfonic acid include CF₃SO₃⁻, C₄F₉SO₃⁻, and C₈F₁₇SO₃⁻.

Specific examples of the anions of perhalogenated Lewis acid include PF₆⁻, SbF₆⁻, BF₄⁻, AsF₆⁻, and FeCl₄⁻.

Specific examples of the anions of perfluoroalkyl sulfonimide include CF₃SO₂—N⁻—SO₂CF₃, and C₄F₉SO₂—N⁻—SO₂C₄F₉.

Specific examples of the anions of perhalogenated acid include ClO₄⁻, BrO₄⁻, and IO₄⁻.

Specific examples of the anions of alkyl or aryl borate include (C₆H₅)₄B⁻, (C₆F₅)₄B⁻, (p-CH₃C₆H₄)₄B⁻, and (C₆H₄F)₄B⁻.

Specific examples of the onium salt compounds are shown below, but the present invention is not limited thereto.

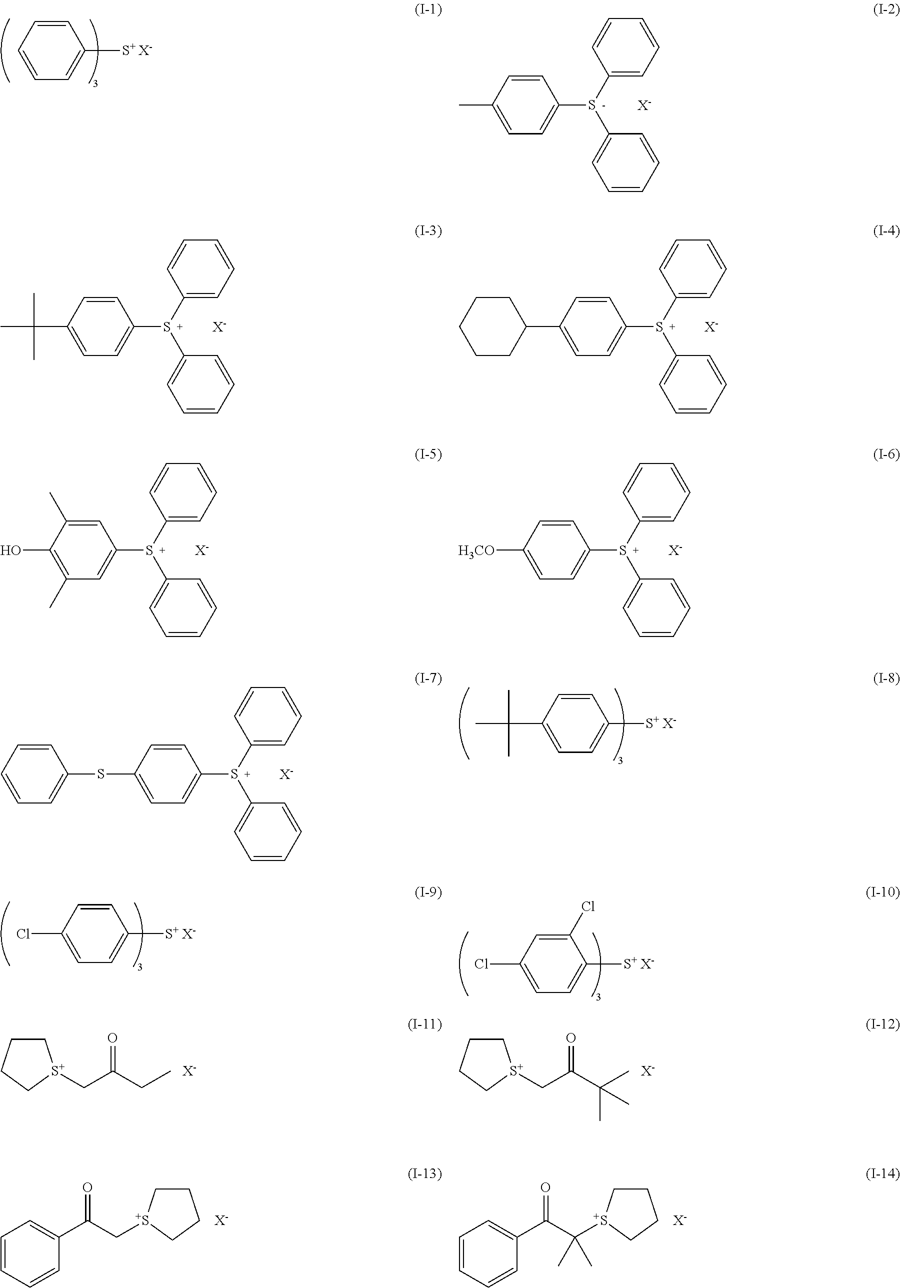

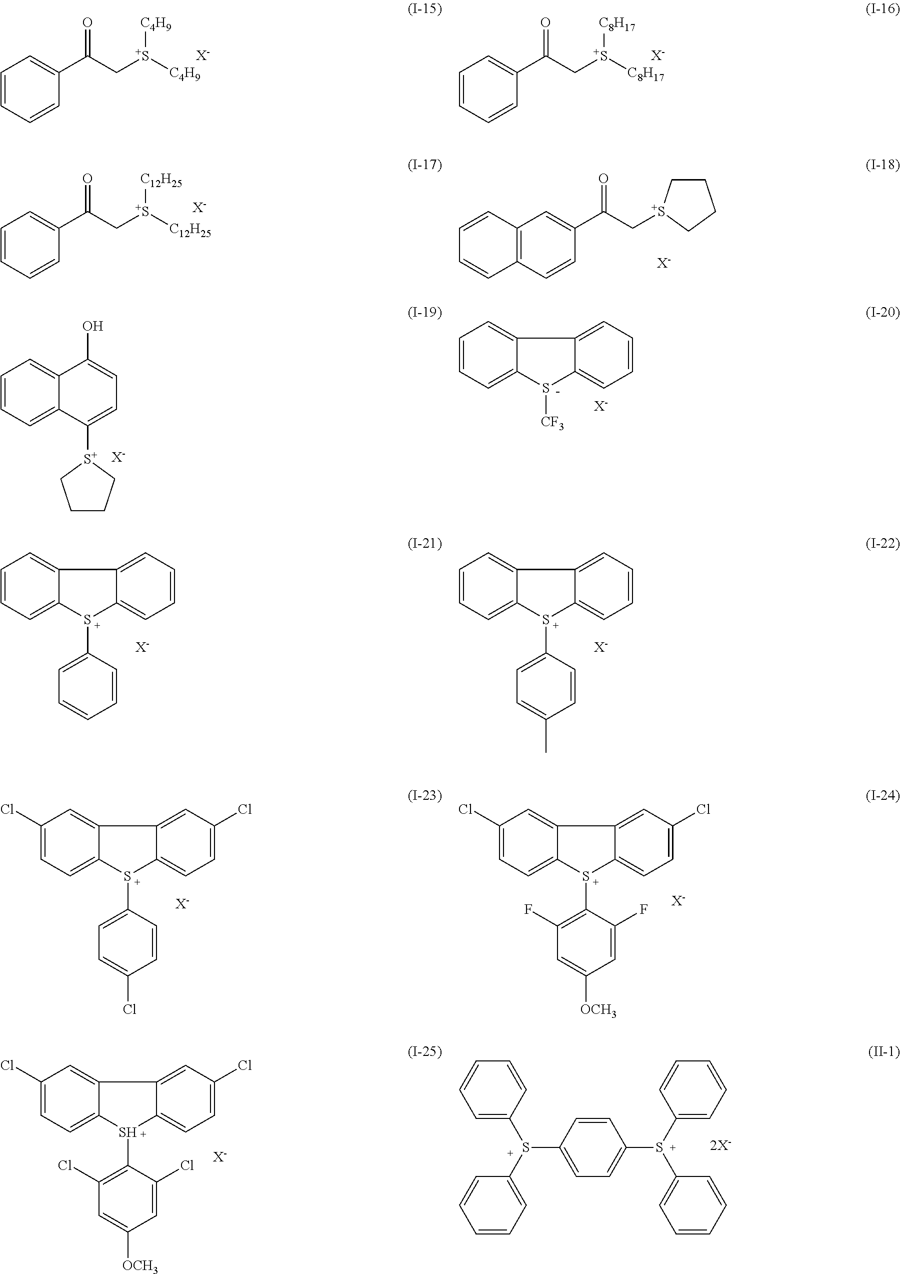

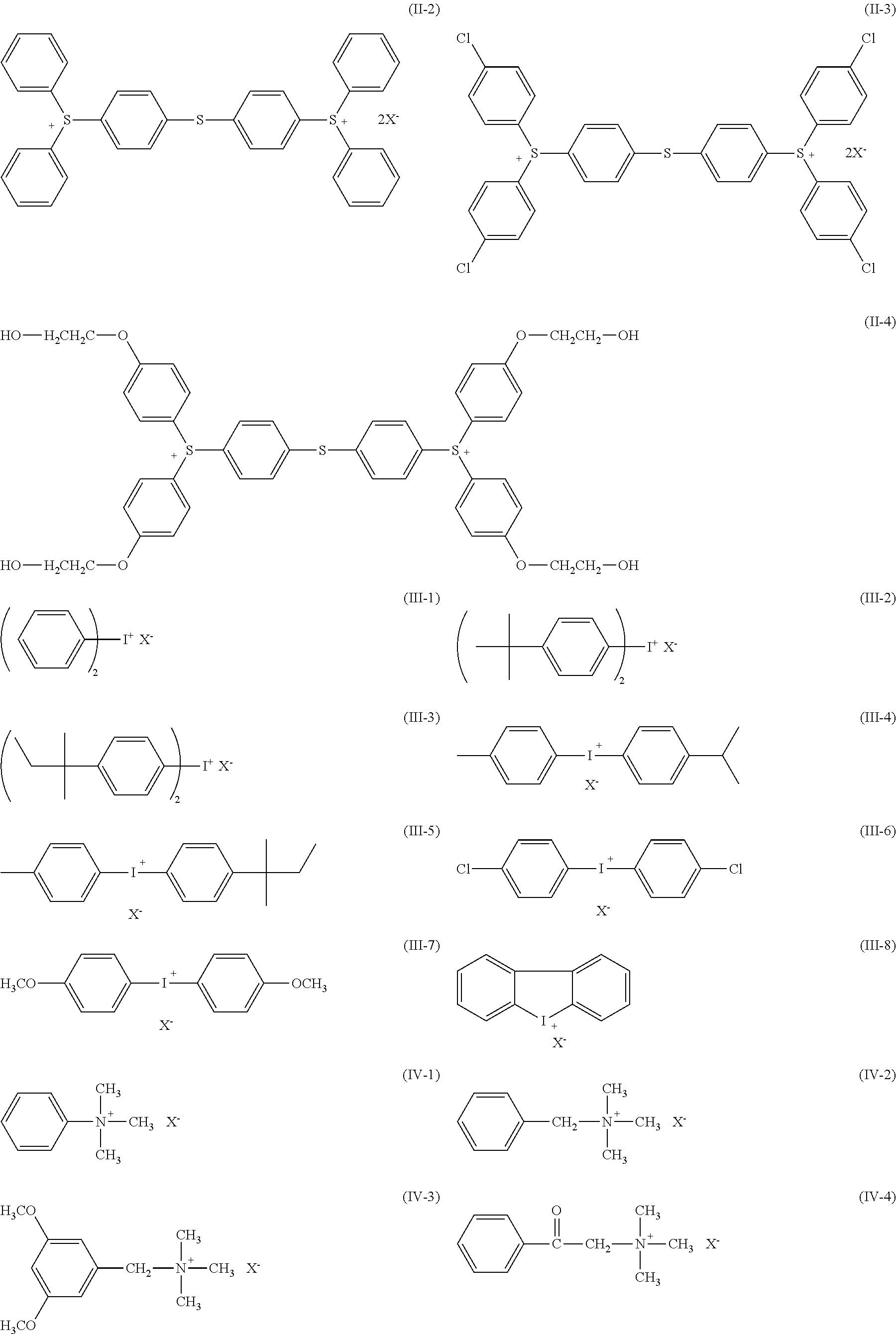

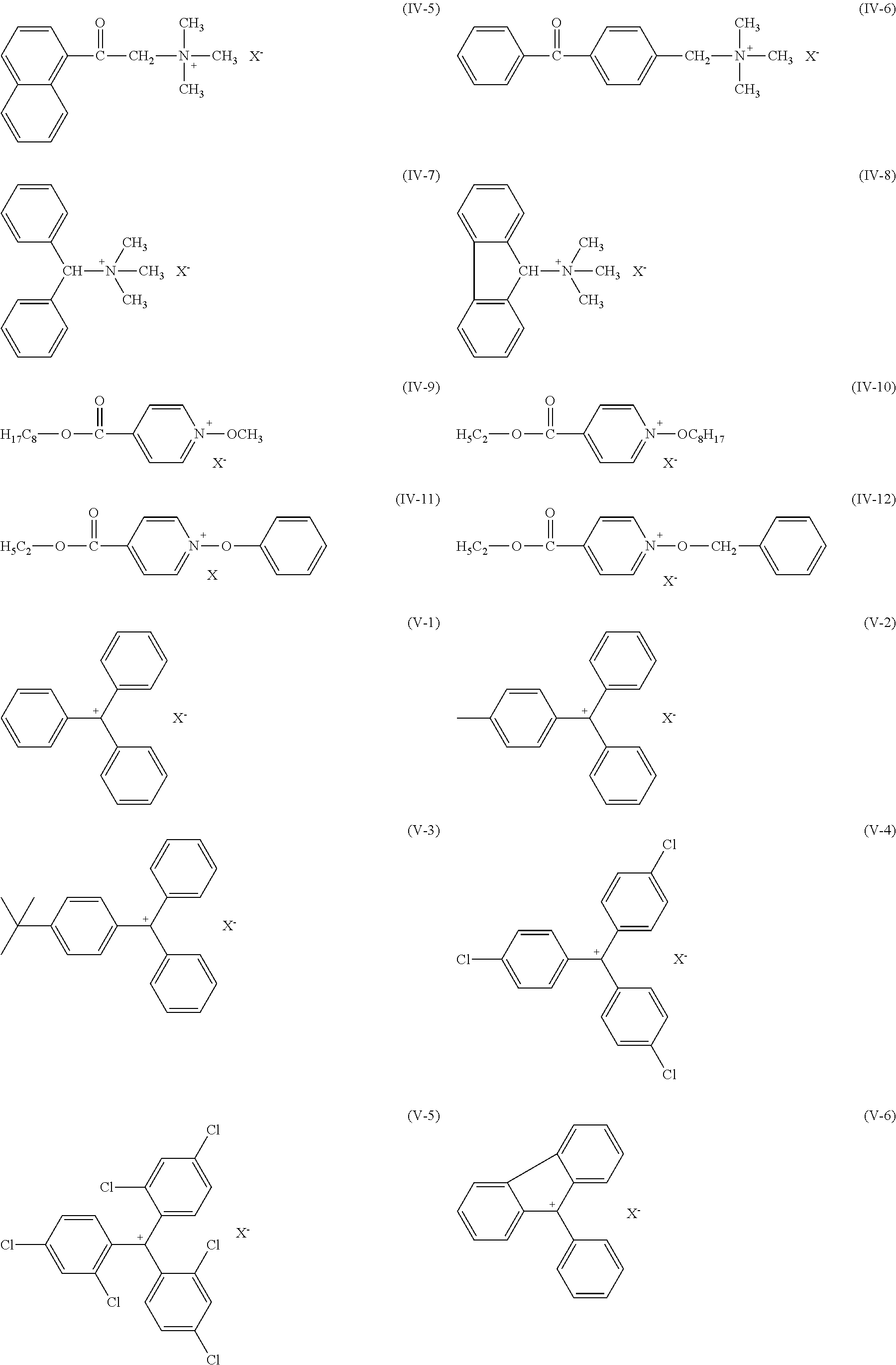

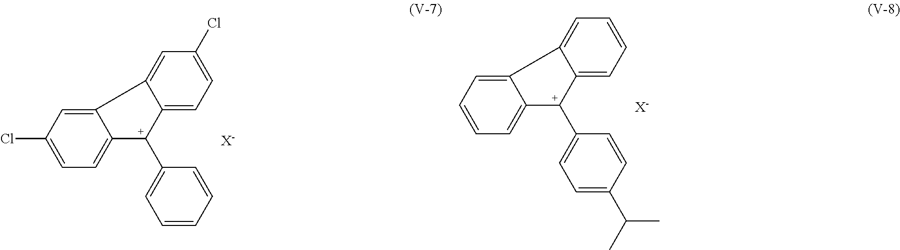

In the above-described specific examples, X⁻ represents PF₆⁻, SbF₆⁻, CF₃SO₃⁻, CH₃PhSO₃⁻, BF₄⁻, (C₆H₅)₄B⁻, RfSO₃⁻, (C₆F₅)₄B⁻, or an anion represented by the following formula: and

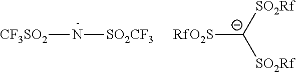

Rf represents a perfluoroalkyl group.

In the present invention, an onium salt compound represented by the following Formula (VI) or (VII) is particularly preferred.

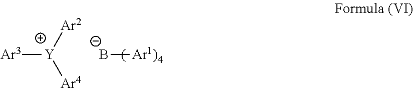

In Formula (VI), Y represents a carbon atom or a sulfur atom, Ar¹ represents an aryl group, and Ar² to Ar⁴ each independently represent an aryl group or an aromatic heterocyclic group. Ar¹ to Ar⁴ may further have a substituent.

Ar¹ is preferably a fluoro-substituted aryl group; more preferably a pentafluorophenyl group or a phenyl group replaced by at least one perfluoroalkyl group; and particularly preferably a pentafluorophenyl group.

The aryl groups or the aromatic heterocyclic groups of Ar² to Ar⁴ have the same meaning as the aryl groups or the aromatic heterocyclic groups of R²¹ to R²³, or R²⁵ to R³³, and are preferably an aryl group, and more preferably a phenyl group. These groups may further have a substituent, and specific examples of the substituents include the above-mentioned substituents of R²¹ to R³³.

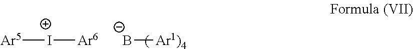

In Formula (VII), Ar¹ represents an aryl group, and Ar⁵ and Ar⁶ each independently represent an aryl group or an aromatic heterocyclic group. Ar¹, Ar⁵, and Ar⁶ may further have a substituent.

Ar¹ has the same meaning as Ar¹ in Formula (VI), and a preferred range thereof is also the same.

Ar⁵ and Ar⁶ each have the same meaning as Ar² to Ar⁴ in Formula (VI), and a preferred range thereof is also the same.

The onium salt compound can be produced by an ordinary chemical synthesis. Moreover, a commercially available reagent or the like can also be used.

One embodiment of a synthetic method of the onium salt compound is represented below, but the present invention is in no way limited thereto. Any other onium salt compound can also be synthesized by a similar technique.

Into a 500 mL volume three-necked flask, 2.68 g oftriphenylsulfonium bromide (manufactured by Tokyo Chemical Industry Co., Ltd.), 5.00 g of a lithium tetrakis(pentafluorophenyl)borate-ethyl ether complex (manufactured by Tokyo Chemical Industry Co., Ltd.), and 146 mL of ethanol are put, the resultant mixture is stirred at room temperature for 2 hours, and then 200 mL of pure water is added thereto, and a precipitated white solid is fractionated by filtration. This white solid is washed with pure water and ethanol, and subjected to vacuum drying, and thus as an onium salt 6.18 g of triphenylsulfonium tetrakis(pentafluorophenyl)borate can be obtained.

2. Oxidizing agent, acid compound, and electron acceptor compound Specific examples of the oxidizing agent to be used as the dopant in the present invention include halogen (Cl₂, Br₂, I₂, ICl, ICl₃, IBr, IF), Lewis acid (PF₅, AsF₅, SbF₅, BF₃, BCl₃, BBr₃, SO₃), a transition metal compound (FeCl₃, FeOCl, TiCl₄, ZrCl₄, HfCl₄, NbF₅, NbCl₅, TaCl₅, MoF₅, MoCl₅, WF₆, WCl₆, UF₆, LnCl₃ (Ln=lanthanoid such as La, Ce, Pr, Nd and Sm), and also O₂, O₃, XeOF₄, (NO₂⁺)(SbF₆⁻), (NO₂⁺)(SbCl₆⁻), (NO₂⁺)(BF₄⁻), FSO₂OOSO₂F, AgClO₄, H₂IrCl₆ and La(NO₃)₃.6H₂O.

Examples of the acidic compound include polyphosphoric acid, a hydroxy compound, a carboxy compound and a sulfonic acid compound as disclosed below, and protic acids (HF, HCl, HNO₃, H₂SO₄, HClO₄, FSO₃H, ClSO₃H, CF₃SO₃H, various organic acids, amino acids, and the like).

Examples of the electron acceptor compound include TCNQ (tetracyanoquinodimethane), tetrafluorotetracyanoquinodimethane, halogenated tetracyanoquinodimethane, 1,1-dicyanovinylene, 1,1,2-tricyanovinylene, benzoquinone, pentafluorophenol, dicyanofluorenone, cyano-fluoroalkylsulfonyl-fluorenone, pyridine, pyrazine, triazine, tetrazine, pyridopyrazine, benzothiadiazole, heterocyclic thiadiazole, porphyrin, phthalocyanine, boron quinolate-based compounds, boron diketonate-based compounds, boron diisoindomethene-based compounds, carborane-based compounds, other boron atom-containing compounds, and the electron acceptor compounds described in Chemistry Letter, 1991, pp. 1707-1710.

—Polyphosphoric acid—

Polyphosphoric acid includes diphosphoric acid, pyrophosphoric acid, triphosphoric acid, tetraphosphoric acid, metaphosphoric acid and polyphosphoric acid, and a salt thereof. Polyphosphoric acid may be a mixture thereof. In the present invention, polyphosphoric acid includes preferably diphosphoric acid, pyrophosphoric acid, triphosphoric acid and polyphosphoric acid, and further preferably, polyphosphoric acid. Polyphosphoric acid can be synthesized by heating H₃PO₄ with a sufficient amount of P₄O₁₀ (phosphoric anhydride), or by heating H₃PO₄ to remove water.

### —Hydroxy Compound—

The hydroxy compound only needs to include at least one hydroxyl group, and preferably, a phenolic hydroxyl group. The hydroxy compound is preferably a compound represented by Formula (VIII).

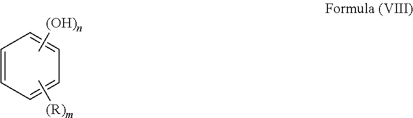

In Formula (VIII), R represents a sulfo group, a halogen atom, an alkyl group, an aryl group, a carboxy group, an alkoxycarbonyl group, n represents 1 to 6, m represents 0 to 5.

R is preferably a sulfo group, an alkyl group, an aryl group, a carboxy group, an alkoxycarbonyl group, more preferably a sulfo group.

n is preferably 1 to 5, more preferably 1 to 4, further preferably 1 to 3.

m is preferably 0 to 5, preferably 0 to 4, more preferably 0 to 3.

—Carboxy compound—

The carboxy compound only needs to include at least one carboxy group, and is preferably a compound represented by Formula (IX) or (X).

HOOC-A-COOH Formula (IX)

In Formula (IX), a symbol A represents a divalent linking group. The divalent linking group is preferably a combination of an alkylene group, an arylene group or an alkenylene group with an oxygen atom, a sulfur atom or a nitrogen atom; and more preferably a combination of an alkylene group or an arylene group with an oxygen atom or a sulfur atom. In addition, when the divalent linking group is a combination of an alkylene group and a sulfur atom, the compound corresponds also to a thioether compound. Use of such a thioether compound is also preferred.

When the divalent linking group represented by A includes an alkylene group, the alkylene group may have a substituent. The substituent is preferably an alkyl group, and more preferably has a carboxy group as a substituent.

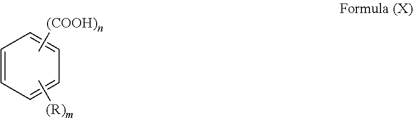

In Formula (X), R represents a sulfo group, a halogen atom, an alkyl group, an aryl group, a hydroxy group, an alkoxycarbonyl group, n represents 1 to 6, m represents 0 to 5.

R is preferably a sulfo group, an alkyl group, an aryl group, a hydroxy group, an alkoxycarbonyl group, more preferably a sulfo group, an alkoxycarbonyl group.

n is preferably 1 to 5, more preferably 1 to 4, further preferably 1 to 3.

m is 0 to 5, preferably 0 to 4, more preferably 0 to 3.

—Sulfonic acid compound—

A sulfonic acid compound has at least one sulfo group, and preferably has two or more sulfo groups. The sulfonic acid compound is preferably replaced by an aryl group or an alkyl group, and more preferably, an aryl group.

In the hydroxy compound and the carboxy compound as described above, a compound having a sulfo group as a substituent is also preferred.

It is not essential to use these dopants, but when dopants are used, a further enhancement of the thermoelectric conversion characteristics can be expected as a result of an enhancement of electrical conductivity, and thus it is preferable. When dopants are used, one kind can be used alone, or two or more kinds can be used in combination. Regarding the amount of use of the dopant, from the viewpoint of controlling the optimal carrier concentration, it is preferable to use the dopant in an amount of 0 part to 60 parts by mass, more preferably 2 parts to 50 parts by mass, and further preferably 5 to 40 parts by mass, relative to 100 parts by mass of the conjugated polymer.

From the viewpoints of enhancing dispersibility or film-forming property of the thermoelectric conversion material, it is preferable to use, among the dopants described above, an onium salt compound. An onium salt compound is neutral before acid release, and is decomposed when energy such as light or heat is applied, to generate an acid, and this acid causes a doping effect to be developed. Therefore, a thermoelectric conversion material is shaped and processed into a desired shape, and then doping is carried out by light irradiation or the like, and thus a doping effect can be exhibited. Furthermore, the thermoelectric conversion material before acid release is neutral, and various components such as the conjugated polymer and CNT are uniformly dissolved or dispersed in the material without aggregating or precipitating the conjugated polymer. Due to the uniform solubility or dispersibility of this material, excellent electrical conductivity can be exhibited after doping. Also, coating property or film-forming property of the material becomes satisfactory, moldability or processability into a thermoelectric conversion layer or the like is also excellent.

[Thermal excitation assist agent]

The thermoelectric conversion material of the present invention preferably contains a thermal excitation assist agent. A thermal excitation assist agent is a substance having a molecular orbital with a particular energy level difference relative to the energy level of the molecular orbital of the conjugated polymer, and when used together with the conjugated polymer, the thermal excitation assist agent can increase the thermal excitation efficiency and thereby enhance the thermopower of the thermoelectric conversion material.

The thermal excitation assist agent used in the present invention is a compound having a LUMO (Lowest Unoccupied Molecular Orbital) with a lower energy level than that of the LUMO of a conjugated polymer, and refers to a compound which does not form a doping level in the conjugated polymer. The dopant described above is a compound that forms a doping level in the conjugated polymer, and forms a doping level irrespective of the presence or absence of a thermal excitation assist agent.

Whether or not the doping level is formed in the conjugated polymer can be evaluated by measurement of absorption spectra. In the present invention, a compound that forms the doping level or a compound that does not form the doping level refer to ones evaluated by the following method.

—Method for evaluating presence or absence of doping level formation—

Conjugated polymer A before doping and another component B are mixed in a weight ratio of 1:1, and absorption spectra of a thin-filmed sample is observed. As a result, when a new absorption peak different from absorption peaks of conjugated polymer A alone or component B alone appears, and a wavelength of the new absorption peak is on a side of wavelength longer than an absorption maximum wavelength of electrically conductive polymer A, the doping level is judged to be generated. In this case, component B is defined as a dopant.

LUMO of the thermal excitation assist agent has a lower energy level in comparison with LUMO of the conjugated polymer, and functions as an acceptor level of thermal excitation electrons generated from HOMO (Highest Occupied Molecular Orbital) of the conjugated polymer.

Further, when an absolute value of the energy level of HOMO of the conjugated polymer and an absolute value of the energy level of LUMO of the thermal excitation assist agent have relation satisfying the following numerical expression (I), the thermoelectric conversion material has excellent thermopower.

0.1 eV≦|HOMO of the conjugated polymer|−|LUMO of the thermal excitation assist agent|≦1.9 eV Numerical expression (I)

The above-described numerical expression (I) represents an energy difference between HOMO of the conjugated polymer and LUMO of the thermal excitation assist agent, and when the difference is smaller than 0.1 eV (including a case where the energy level of LUMO of the thermal excitation assist agent is lower than the energy level of HOMO of the electrically conductive polymer), activation energy of electron transfer between HOMO (donor) of the conjugated polymer and LUMO (acceptor) of the thermal excitation assist agent becomes very small, and therefore an oxidation-reduction reaction takes place between the conjugated polymer and the thermal excitation assist agent, resulting in causing aggregation. As a result, aggregation leads to deterioration of film-forming properties of a material and deterioration of electrical conductivity. Conversely, when the energy difference between both orbitals is larger than 1.9 eV, the energy difference becomes by far larger than thermal excitation energy, and therefore a thermal excitation carrier is hardly generated, more specifically, an effect of addition of the thermal excitation assist agent almost vanishes. The energy difference between both orbitals is required to be within the range of the above-described numerical expression (I) for improving the thermopower of the thermoelectric conversion material.

In addition, with regard to the energy levels of HOMO and LUMO of the conjugated polymer and the thermal excitation assist agent, the HOMO energy level can be measured by preparing a coating film of each single component on a glass substrate, and measuring the HOMO level according to photoelectron spectroscopy. The LUMO level can be calculated by measuring a band gap using a UV-Vis spectrophotometer, and then adding the HOMO energy as measured above. In the present invention, with regard to the energy levels of HOMO and LUMO of the conjugated polymer and the thermal excitation assist agent, values measured and calculated by the method are used.

When a thermal excitation assist agent is used, the thermal excitation efficiency is increased, and the number of thermal excitation carriers is increased, so that the thermopower of the thermoelectric conversion material is increased. Such effect caused by a thermal excitation assist agent is different from the technique of enhancing the thermoelectric conversion performance by the doping effect on the conjugated polymer.

As can be seen from the formula (A), for enhancement of the thermoelectric conversion performance of a thermoelectric conversion material, it is required to increase the absolute value of the Seebeck coefficient S and the electrical conductivity c of the material, and to decrease the thermal conductivity κ. Meanwhile, the Seebeck coefficient is the thermopower per absolute temperature 1 K.

The thermal excitation assist agent enhances the thermoelectric conversion performance by increasing the Seebeck coefficient. When a thermal excitation assist agent is used, electrons generated by thermal excitation are present in the LUMO of the thermal excitation assist agent, which is an acceptor level. Therefore, holes on the conjugated polymer and electrons on the thermal excitation assist agent are exist in a physically isolated manner. Therefore, it becomes difficult for the doping level of the conjugated polymer to be saturated by the electrons generated by thermal excitation, and the Seebeck coefficient can be increased.

The thermal excitation assist agent is preferably a polymer compound including at least one kind of structure selected from a benzothiadiazole skeleton, a benzothiazole skeleton, a dithienosilole skeleton, a cyclopentadithiophene skeleton, a thienothiophene skeleton, a thiophene skeleton, a fluorene skeleton and a phenylenevinylene skeleton, or a fullerene-based compound, a phthalocyanine-based compound, a perylenedicarboxylmide-based compound or a tetracyanoquinodimethane-based compound; and more preferably a polymer compound including at least one kind of structure selected from a benzothiadiazole skeleton, a benzothiazole skeleton, a dithienosilole skeleton, a cyclopentadithiophene skeleton and a thienothiophene skeleton, or a fullerene-based compound, a phthalocyanine-based compound, a perylenedicarboxylmide-based compound or a tetracyanoquinodimethane-based compound.

Specific examples of the thermal excitation assist agents satisfying the above-mentioned features include the following ones, but the present invention is not limited thereto. In the following exemplified compounds, n represents an integer (preferably an integer of 10 or more), and Me represents a methyl group.

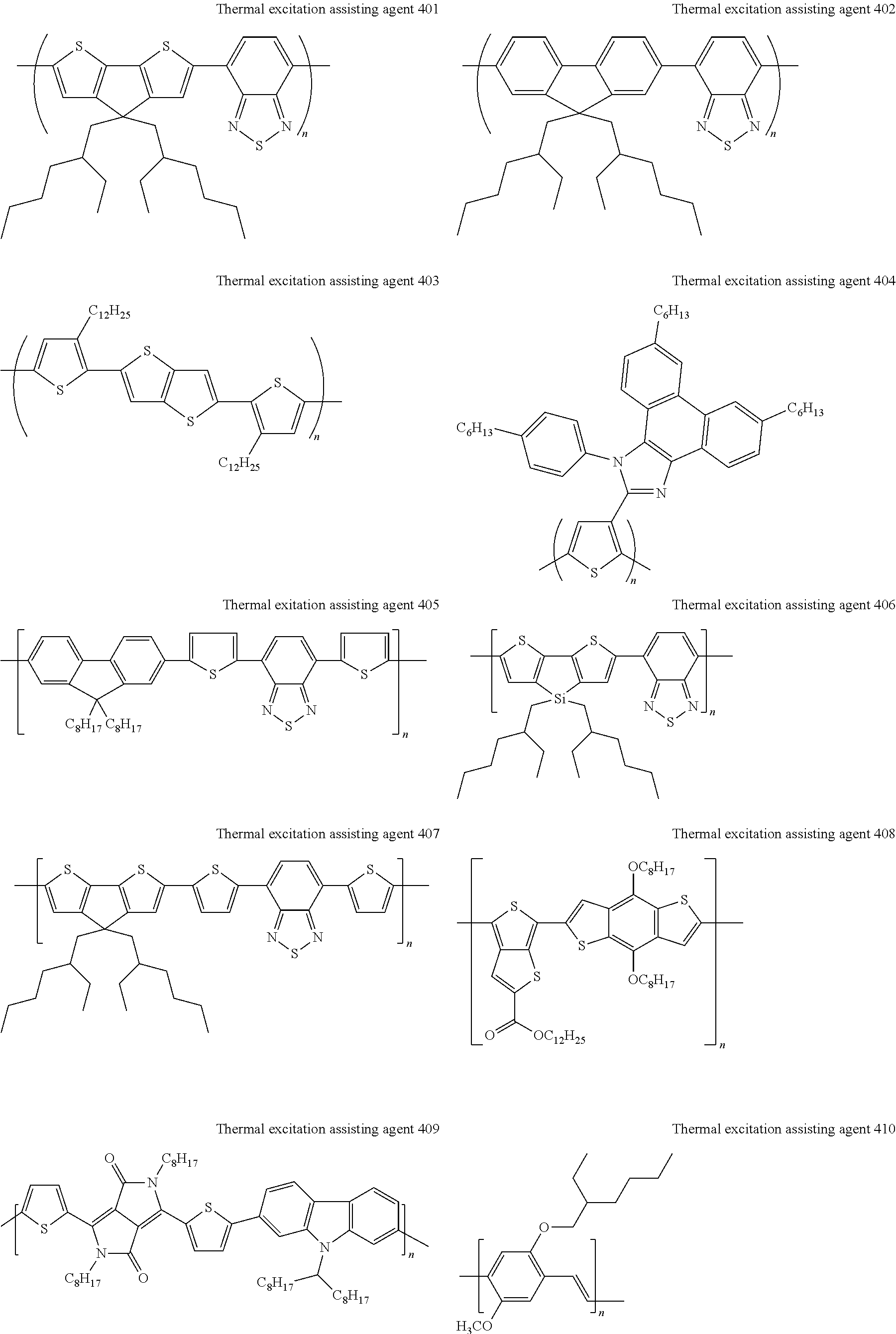

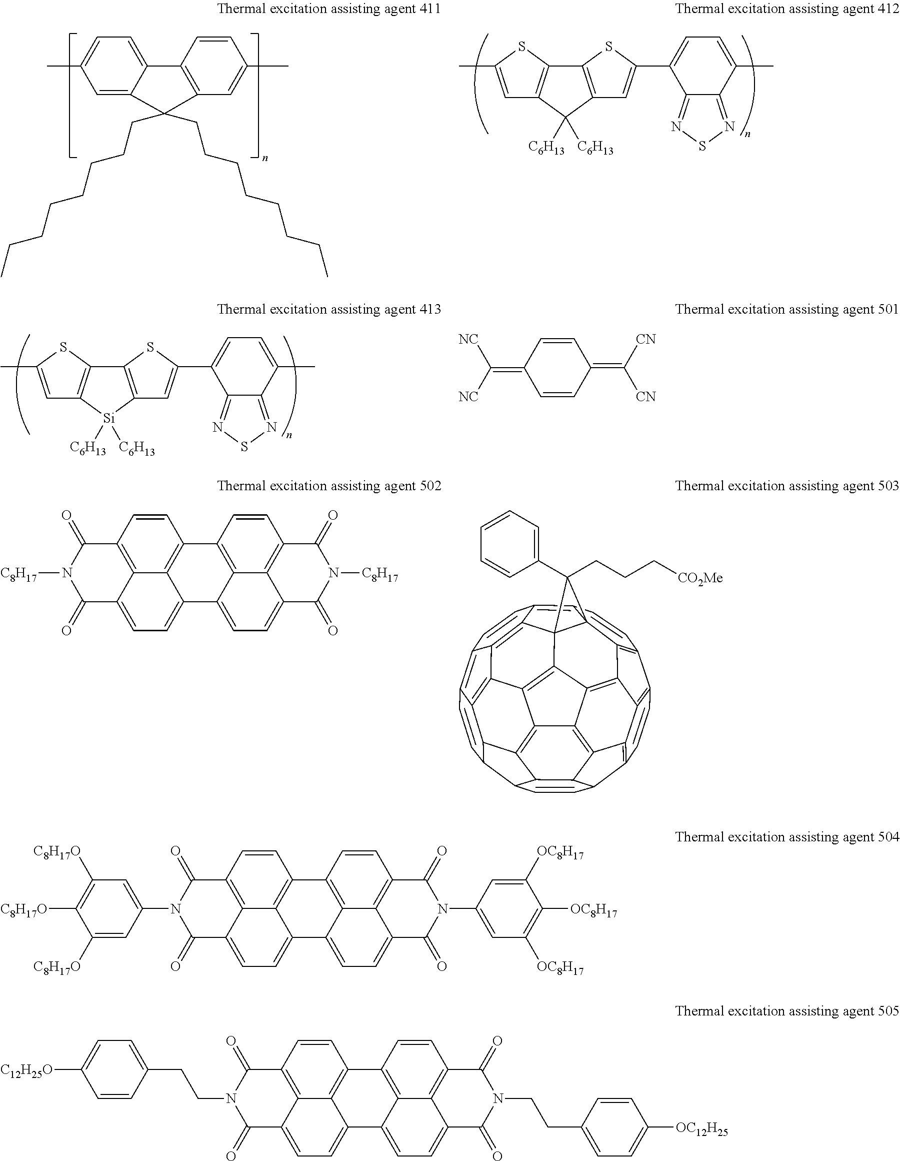

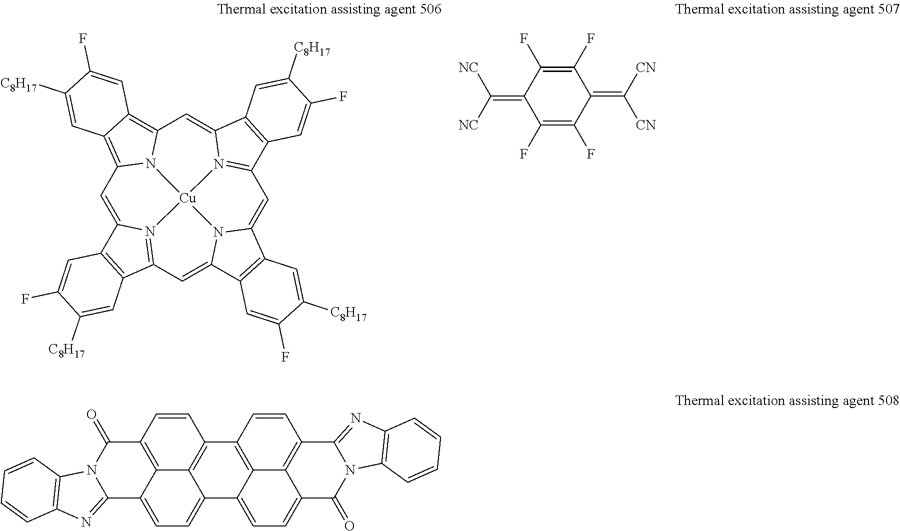

In the thermoelectric conversion material of the present invention, the above-described thermal excitation assist agent can be used alone in one kind or in combination with two or more kinds.

The content of the thermal excitation assist agent in the thermoelectric conversion material is, in the total solid content, preferably, 0% to 35% by mass, more preferably, 3% to 25% by mass, and particularly preferably, 5% to 20% by mass.

Furthermore, it is preferable to use the thermal excitation assist agent in an amount of 0 part to 100 parts by mass, more preferably 5 parts to 70 parts by mass, and further preferably 10 parts to 50 parts by mass, relative to 100 parts by mass of the conjugated polymer.

### [Other Component]

In addition to the above-described component, the thermoelectric conversion material of the present invention may contain an antioxidant, a light-resistant stabilizer, a heat-resistant stabilizer and a plasticizer. The content of these components is preferably 5% by mass or less, and more preferably 0% to 2% by mass, relative to the total solid content of the material.

Specific examples of the antioxidant include IRGANOX 1010 (manufactured by Nihon Ciba-Geigy K.K.), SUMILIZER GA-80 (manufactured by Sumitomo Chemical Co., Ltd.), SUMILIZER GS (manufactured by Sumitomo Chemical Co., Ltd.) and SUMILIZER GM (manufactured by Sumitomo Chemical Co., Ltd.).

Specific examples of the light-resistant stabilizer include TINUVIN 234 (manufactured by BASF), CHIMASSORB 81 (manufactured by BASF) and CYASORB UV-3853 (manufactured by Sun Chemical Corporation).

Specific examples of the heat-resistant stabilizer include IRGANOX 1726 (manufactured by BASF).

Specific examples of the plasticizer include ADK CIZER RS (manufactured by ADEKA Corporation).

### [Thermoelectric Conversion Material]

The thermoelectric conversion material of the present invention has the moisture content preferably in an amount of 0.01% by mass or more to 15% by mass or less. In a thermoelectric conversion material containing the conjugated polymer and the carbon nanotube as essential components, when the moisture content is adjusted to the above range, high thermoelectric conversion performance can be obtained while maintaining excellent coating property and film-forming property. Furthermore, even when the material is put to use as a thermoelectric conversion material under high temperature conditions, corrosion of electrodes or decomposition of the material itself can be suppressed. The thermoelectric conversion material is generally used in a high temperature state over a long time, and therefore, corrosion of electrodes or a decomposition of the material is likely to occur due to water contained in the material. Such problems can be ameliorated by adjusting the moisture content to the range described above.

The moisture content of the thermoelectric conversion material is more preferably from 0.01% by mass to 10% by mass, and further preferably from 0.1% by mass to 5% by mass.

The moisture content of a material can be evaluated by measuring the equilibrium moisture content at a constant temperature and a constant humidity. The equilibrium moisture content can be measured, after leaving the material to stand at 25° C. and 60% RH for 6 hours to reach equilibrium, by the Karl Fischer method with a moisture analyzer and a sample drying apparatus (CA-03 and VA-05, all by Mitsubishi Chemical Corp.), and can be calculated by dividing the amount of moisture (g) by the sample weight (g).

The moisture content of the material can be controlled by leaving a sample to stand inside a constant temperature constant humidity apparatus (temperature 25° C., humidity 85% RH) (in the case of increasing the moisture content), or by drying in a vacuum dryer (temperature 25° C.) (in the case of decreasing the moisture content). Furthermore, the moisture content can also be controlled by adding a necessary amount of water to the solvent when the material is prepared (in the case of increasing the moisture content), or preparing a composition (film or the like) in a glove box under a nitrogen atmosphere using a dehydrating solvent (for example, various dehydrating solvents manufactured by Wako Pure Chemical Industries, Ltd. may be used) (in the case of decreasing the moisture content).

It is preferable that such a moisture content controlling treatment be carried out after the material is processed by film forming. For example, it is preferable to adjust the moisture content to the range described above, by mixing or dispersing the components such as CNT and a conjugated polymer in a solvent, subjecting the mixture to molding, film forming or the like, and adjusting the moisture content.

### [Preparation of Thermoelectric Conversion Material]

The thermoelectric conversion material of the present invention can be prepared by mixing the various components described above. Preferably, the thermoelectric conversion material is prepared by adding CNT and the conjugated polymer to the solvent to mix, and dissolving or dispersing the components. At this time, the components in the material are preferably such that CNT is in a dispersed state, while other components such as the conjugated polymer are in a dispersed or dissolved state; and more preferably such that the components other than CNT are in a dissolved state. When the components other than CNT are in a dissolved state, it is preferable because an effect of suppressing a decrease in the electrical conductivity by grain boundaries may be obtained. Meanwhile, the dispersed state as described above refers to a state of molecular aggregation having a particle size to the extent that even though the material is stored for a long time (as a rough indication, for one month or more), sedimentation does not occur in the solvent, and the dissolved state refers to a state in which the component is solvated in the state of individual molecules in the solvent.

There are no particular limitations on the method for preparing a thermoelectric conversion material, and the material can be prepared at normal temperature and normal pressure using a conventional mixing apparatus or the like. For example, the material may be prepared by dissolving or dispersing various components in a solvent by stirring, shaking, or kneading. An ultrasonication treatment may also be carried out in order to accelerate dissolution or dispersion.

In the above dispersion process, dispersibility of CNT can be increased by heating the solvent to a temperature higher than or equal to room temperature and lower than or equal to the boiling point, by prolonging the dispersion time, or by increasing the application intensity of stirring, infiltration, kneading, ultrasonic waves and the like.

### [Thermoelectric Conversion Element]

The thermoelectric conversion element of the present invention may be any element using the thermoelectric conversion material of the present invention in a thermoelectric conversion layer. The thermoelectric conversion layer may be any layer obtainable by shaping the thermoelectric conversion material on a substrate, and there are no particular limitations on the shape, preparation method and the like. The thermoelectric conversion material of the present invention has high dispersibility of CNT, and the thermoelectric conversion layer can be formed by coating the material on a substrate and forming a film.

The film forming method is not particularly limited, and for example, known methods such as spin coating, extrusion die coating, blade coating, bar coating, screen printing, stencil printing, roll coating, curtain coating, spray coating, dip coating, and an inkjet method, can be used.

After the coating, a drying process is carried out if necessary. For example, a solvent can be volatilized and dried by blowing hot air.

As the substrate, a base material such as glass, transparent ceramics, a metal and a plastic film can be used. Specific examples of the plastic film that can be used in the present invention include a polyester film such as a polyethylene terephthalate film, a polyethylene isophthalate film, a polyethylene naphthalate film, a polybutylene terephthalate film, a poly(1,4-cyclohexylene dimethylene terephthalate) film, a polyethylene-2,6-phthalenedicarboxylate film, and a polyester film of bisphenol A and isophthalic acid and terephthalic acid; a polycycloolefin film, in a trade name, such as Zeonor Film (manufactured by Zeon Corporation), Arton Film (manufactured by JSR Corporation) and SUMILITE FS1700 (manufactured by SUMITOMO BAKELITE CO., LTD.); a polyimide film, in a trade name, Kapton (manufactured by DU PONT-TORAY CO., LTD.), APICAL (manufactured by Kaneka Corporation), Upilex (Ube Industries, Ltd.) and POMIRAN (manufactured by Arakawa Chemical Industries, Ltd.); a polycarbonate film, in a trade name, such as PURE ACE (manufactured by Teijin Chemicals Ltd.) and ELMEC (manufactured by Kaneka Corporation); a polyether ether ketone film, in a trade name, such as SUMILITE FS1100 (manufactured by SUMITOMO BAKELITE CO., LTD.); and a polyphenylsulfide film, in a trade name, such as TORELINA (manufactured by Toray Industries, Inc.). Appropriate selection is allowed depending on using conditions and an environment, but from viewpoints of easy availability, heat resistance, preferably, of 100° C. or higher, profitability and an effect, a commercially available polyethylene terephthalate film, polyethylene naphthalate film, various kinds of polyimide films, polycarbonate film, or the like are preferred.

In particular, a substrate on which various kinds of electrode materials are arranged on a compression bonding surface with the thermoelectric conversion layer is preferably used. As the electrode material, a transparent electrode such as ITO and ZnO, a metal electrode such as silver, copper, gold and aluminum, a carbon material such as CNT and graphene, an organic material such as PEDOT/PSS, a conductive paste into which conductive particulates such as silver and carbon are dispersed, and a conductive paste containing a metal nanowire of silver, copper and aluminum, can be used.

### (Doping by Energy Application)

When the thermoelectric conversion material contains the onium salt compound as a dopant, it is preferable to enhance electrical conductivity by subjecting, after film forming, the relevant film to irradiation with active energy ray or heating to perform a doping treatment. This treatment causes generation of acid from the onium salt compound, and when this acid protonates the conjugated polymer, the conjugated polymer is doped with a positive charge (p-type doping).

The active energy rays include radiation and electromagnetic waves, and the radiation includes particle beams (high-speed particle beams) and electromagnetic radiation. Specific examples of the particle beams include charged particle beams such as alpha rays (α-rays), beta rays (β-rays), proton beams, electron beams (meaning ones accelerating an electron by means of an accelerator without depending on nuclear decay), and deuteron beams; non-charged particle beams such as neutron beams; and cosmic rays. Specific examples of the electromagnetic radiation include gamma rays (γ-rays) and X-rays (X-rays and soft X-rays). Specific examples of the electromagnetic waves include radio waves, infrared rays, visible rays, ultraviolet rays (near-ultraviolet rays, far-ultraviolet rays, and extreme ultraviolet rays), X-rays, and gamma rays. Types of active energy rays used in the present invention are not particularly limited. For example, electromagnetic waves having a wavelength near a maximum absorption wavelength of the onium salt compound may be selected as appropriate.

Among these active energy rays, from viewpoints of the doping effect and safety, ultraviolet rays, visible rays, or infrared rays are preferred. Specifically, the active energy rays include rays having a maximum emission wavelength in the range of 240 to 1,100 nm, preferably in the range of 240 to 850 nm, and more preferably in the range of 240 to 670 nm.

For irradiation with active energy rays, radiation equipment or electromagnetic wave irradiation equipment is used. A wavelength of radiation or electromagnetic waves for irradiation is not particularly limited, and one allowing radiation or electromagnetic waves in a wavelength region corresponding to a response wavelength of the onium salt compound may be selected.

Specific examples of the equipment allowing radiation or irradiation with electromagnetic waves include exposure equipment using as a light source an LED lamp, a mercury lamp such as a high-pressure mercury lamp, an ultra-high pressure mercury lamp, a Deep UV lamp, and a low-pressure UV lamp, a halide lamp, a xenon flash lamp, a metal halide lamp, an excimer lamp such as an ArF excimer lamp and a KrF excimer lamp, an extreme ultraviolet ray lamp, electron beams, and an X-ray lamp. Irradiation with ultraviolet rays can be applied using ordinary ultraviolet ray irradiation equipment such as commercially available ultraviolet ray irradiation equipment for curing/bonding/exposure use (for example, SP9-250UB, USHIO INC.).

Exposure time and an amount of light may be selected as appropriate in consideration of a kind of onium salt compound to be used and the doping effect. Specific examples of the amount of light include 10 mJ/cm² to 10 J/cm², and preferably 50 mJ/cm² to 5 J/cm².

When doping is carried out by heating, a formed thermoelectric conversion layer may be heated to a temperature higher than or equal to the temperature at which the onium salt compound generates acid. A heating temperature is preferably 50° C. to 200° C., and more preferably 70° C. to 150° C. Heating time is preferably 1 minute to 60 minutes, and more preferably 3 minutes to 30 minutes.

The timing of the doping treatment is not particularly limited, but it is preferable to perform the doping treatment after processing the material by film forming or the like. Furthermore, when a treatment for controlling the moisture content is carried out, it is preferable to perform the doping treatment after the moisture content controlling treatment.

### [Configuration of Thermoelectric Conversion Element]

The thermoelectric conversion element of the present invention may be any element having a thermoelectric conversion layer using the thermoelectric conversion material of the present invention, and the configuration thereof is not particularly limited. Preferably, the thermoelectric conversion element is an element including a substrate (base material) and a thermoelectric conversion layer provided on the substrate, and more preferably, the thermoelectric conversion element is an element further having electrodes that electrically connect these. Even more preferably, the thermoelectric conversion element is an element having a pair of electrodes provided on a substrate, and a thermoelectric conversion layer disposed between the electrodes.

The thermoelectric conversion element of the present invention may has one thermoelectric conversion layer or two or more layers, preferably has two or more thermoelectric conversion layers.

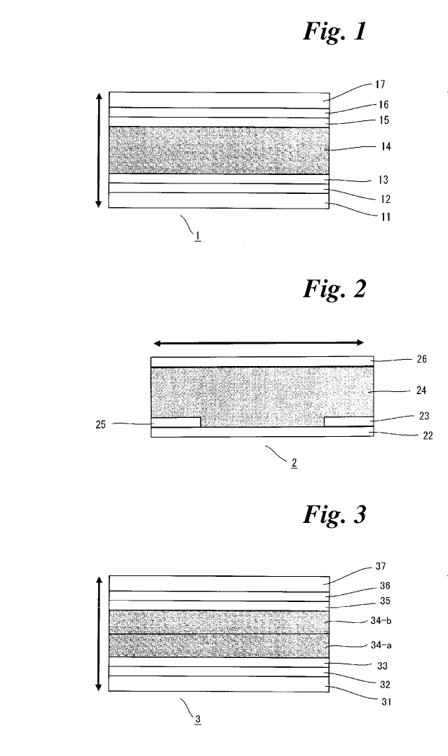

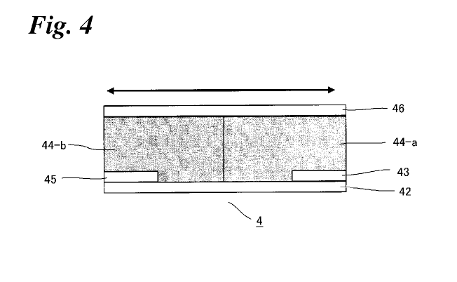

Specific examples of a structure of the thermoelectric conversion element of the present invention include structures of elements shown in FIG. 1 to FIG. 4. Element (1) in FIG. 1 and element (2) in FIG. 2 show a thermoelectric conversion element having a mono-layered thermoelectric conversion layer, and element (3) in FIG. 3 and element (4) in FIG. 4 show a thermoelectric conversion element having a multi-layered thermoelectric conversion layer, respectively. In FIG. 1 to FIG. 4, arrows show directions of temperature difference, respectively, during use of the thermoelectric conversion elements.

Element (1) shown in FIG. 1 and element (3) shown in FIG. 3 have, on first substrate (12, 32), a pair of electrodes including first electrode (13, 33) and second electrode (15, 35), and have layer (14, 34-a, 34-b) of the thermoelectric conversion material of the present invention between the electrodes. In element (3) shown in FIG. 3, a thermoelectric conversion layer includes first thermoelectric conversion layer (34-a) and second thermoelectric conversion layer (34-b), and the layers are laminated in a direction of temperature difference (in an arrow direction). Second electrode (15, 35) is arranged on second substrate (16, 36), and metal plate (11, 17, 31, 37) is arranged oppositely with each other on an outside of first substrate (12, 32) and second substrate (16, 36).

Element (2) shown in FIG. 2 and element (4) shown in FIG. 4 have first electrode (23, 43) and second electrode (25, 45) arranged on first substrate (22, 42), and further have thermoelectric conversion material layer (24, 44-a, 44-b) arranged thereon. In element (4) shown in FIG. 4, a thermoelectric conversion layer includes first thermoelectric conversion layer (44-a) and second thermoelectric conversion layer (44-b), and the layers are laminated in a direction of temperature difference (an arrow direction).

In the thermoelectric conversion element of the present invention, the thermoelectric conversion material of the present invention is preferably arranged in the film form on the substrate, and this substrate is preferably functioned as the above-described first substrate (12, 22, 32, 42). More specifically, it is preferably that the above-mentioned electrode materials are arranged on a substrate surface (compression bonding surface with the thermoelectric conversion material), and the thermoelectric conversion material of the present invention is arranged thereon.

The one surface of the thermoelectric conversion layer thus formed is covered with the substrate. From a viewpoint of protection of the film, it is preferable that the other surface of the layer is also covered with a substrate (second substrate (16, 26, 36 or 46)) by compression-bonding. On the surface (surface to be compression-bonded with the thermoelectric conversion material) of the second substrate (16 or 36), the above-mentioned electrode materials may be previously arranged. Moreover, compression bonding between the second substrate and the thermoelectric conversion material is preferably performed by heating them at about 100° C. to 200° C. from a viewpoint of an improvement in adhesion.

When the element of the present invention has two or more thermoelectric conversion layers, at least one layer of a plurality of thermoelectric conversion layers is formed using the thermoelectric conversion material of the present invention. More specifically, when the thermoelectric conversion element of the present invention has a plurality of the thermoelectric conversion layers, the element may have a plurality of only the thermoelectric conversion layers formed using the thermoelectric conversion material of the present invention, or the element may have the thermoelectric conversion layer formed using the thermoelectric conversion material of the present invention, and a thermoelectric conversion layer formed using other thermoelectric conversion material (hereinafter, referred to also as “second thermoelectric conversion material”).

For the second thermoelectric conversion material, any known thermoelectric conversion material can be used, but the second thermoelectric conversion material is preferably a material containing a conjugated polymer. The conjugated polymer used in the second thermoelectric conversion material is preferably a conjugated polymer (hereinafter, referred to as “second conjugated polymer”) other than the conjugated polymer including at least the repeating units (A) and (B), which is used in the thermoelectric conversion material of the present invention.

Regarding the second conjugated polymer, specifically, a conjugated polymer having a repeating unit derived from at least one kind of a monomer selected from the group consisting of a thiophene-based compound, a pyrrole-based compound, an aniline-based compound, an acetylene-based compound, a p-phenylene-based compound, a p-phenylene-vinylene-based compound, a p-phenylene-ethynylene-based compound, and derivatives thereof.

The molecular weight of the second conjugated polymer is not particularly limited, and the molecular weight as a weight average molecular weight is preferably 5,000 or more, more preferably 7,000 to 300,000, and further preferably 8,000 to 100,000.

The content of the second conjugated polymer is preferably 3% to 80% by mass, more preferably 5% to 60% by mass, and particularly preferably 10% to 50% by mass, relative to the total solid content of the second thermoelectric conversion material.

The second thermoelectric conversion material may contain a solvent or other components, in addition to the second conjugated polymer.

Examples of the solvent used in the second thermoelectric conversion material include those solvents used in the thermoelectric conversion material of the present invention described above, and examples of the other components include those carbon nanotubes, non-conjugated polymers, dopants, thermal excitation assist agents and the like used in the thermoelectric conversion material of the present invention described above.

The preparation of the second thermoelectric conversion material, the content of each component, the amount of a solvent used or the like can be adjusted in a manner similar to the above-mentioned thermoelectric conversion material of the present invention.

When the thermoelectric conversion element of the present invention has two or more thermoelectric conversion layers, adjacent thermoelectric conversion layers preferably include mutually different kinds of conjugated polymers.

For example, when adjacent thermoelectric conversion layers 1 and 2 are formed by the thermoelectric conversion material of the present invention, it is preferable that the two thermoelectric conversion layers both contain a conjugated polymer having at least the repeating units (A) and (B), but the conjugated polymer contained in the thermoelectric conversion layer 1 and the conjugated polymer contained in the thermoelectric conversion layer 2 have structures that are different from each other. Furthermore, when a thermoelectric conversion layer 1 formed from the thermoelectric conversion material of the present invention and a thermoelectric conversion layer 2 formed from the second thermoelectric conversion material are adjacent, the thermoelectric conversion layer 1 contains a conjugated polymer having at least the repeating units (A) and (B), while the thermoelectric conversion layer 2 contains a second conjugated polymer, the two adjacent layers come to contain conjugated polymers of different kinds.

In the thermoelectric conversion element of the present invention, film thickness of the thermoelectric conversion layer (gross film thickness when the element has two or more thermoelectric conversion layers) is preferably 0.1 μm to 1,000 μm, and more preferably 1 μm to 100 μm. Small film thickness is not preferred because temperature difference becomes hard to be imparted and resistance in the film increases.

In view of handling properties, durability or the like, thickness of each of the first and second substrate is preferably 30 to 3,000 μm, more preferably 50 to 1,000 μm, further preferably 100 to 1,000 μm, and particularly preferably 200 to 800 μm. A too thick substrate may occasionally cause decrease in thermal conductivity, and a too thin substrate may occasionally easily damage the film by external impact.

In general, the thermoelectric conversion element only needs one organic layer in coating and film formation of the conversion layer, and the element can be further simply produced in comparison with a photoelectric conversion element such as an element for an organic thin film solar cell. In particular, the thermoelectric conversion material of the present invention easily can form a film having a film thickness 100 times to 1,000 times thicker than that of the element for the organic thin film solar cell, and as a result, chemical stability to oxygen or moisture in air is improved.

The thermoelectric conversion element of the present invention can be suitably used as a power generation device for an article for thermoelectric generation. Specifically, the thermoelectric conversion element can be suitably used for a generator of hot spring thermal power generation, solar thermal electric conversion or cogeneration, or a power supply for a wrist watch, a semiconductor drive power supply, a power supply for a small sized sensor, or the like.

### EXAMPLES

The present invention will be described in more detail based on the following examples, but the invention is not intended to be limited thereto.

The following conjugated polymers were used in Examples and Comparative Examples.

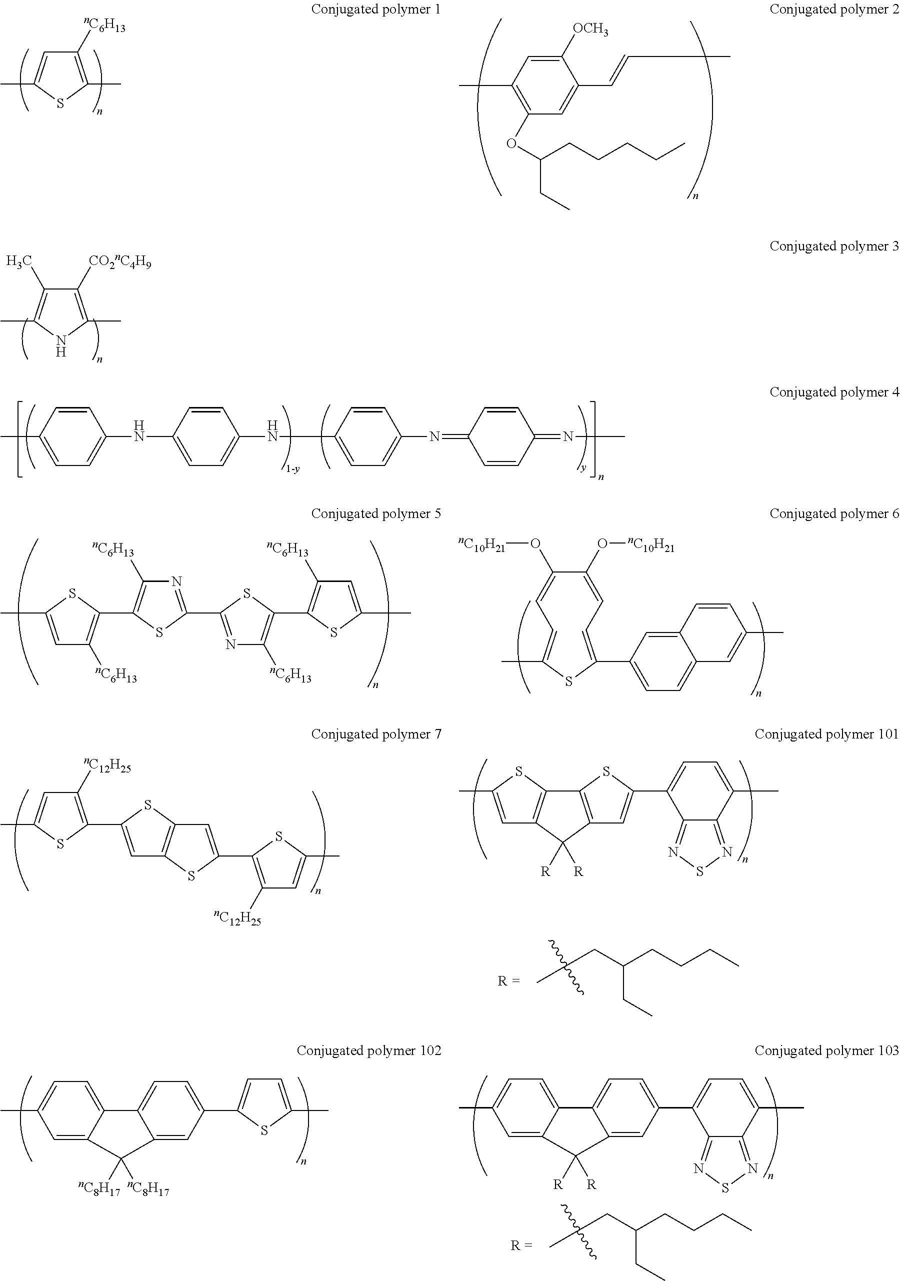

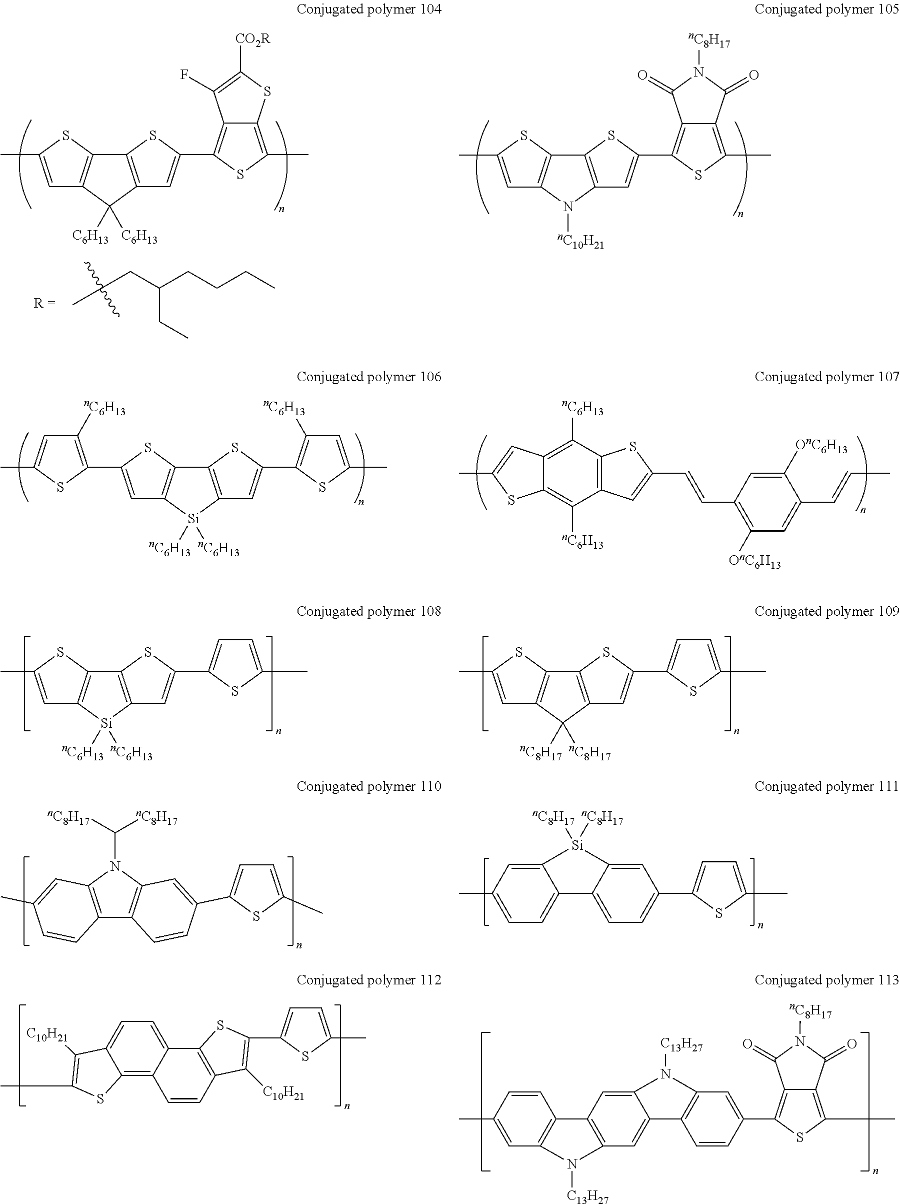

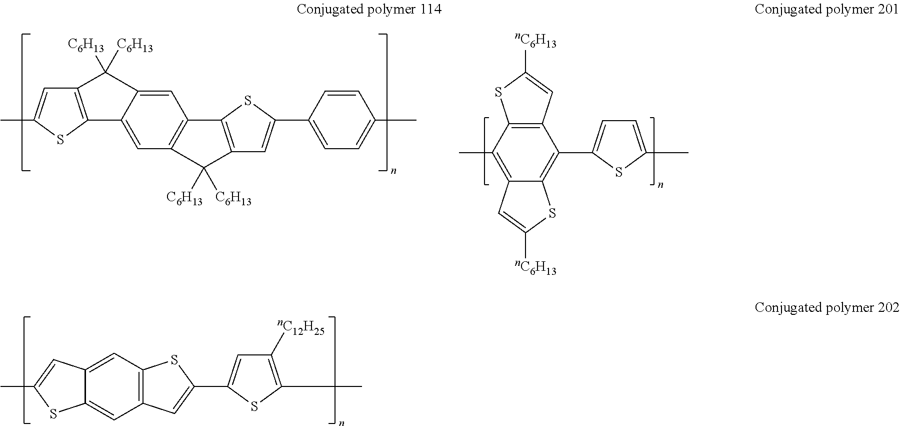

Molecular weight of each of the conjugated polymers used is as described below.

Conjugated polymer 1: Weight average molecular weight=87000
Conjugated polymer 2: Weight average molecular weight=109000
Conjugated polymer 3: Weight average molecular weight=69000
Conjugated polymer 4: Weight average molecular weight=83000
Conjugated polymer 5: Weight average molecular weight=47000
Conjugated polymer 6: Weight average molecular weight=46000
Conjugated polymer 7: Weight average molecular weight=77000
Conjugated polymer 101: Weight average molecular weight=103000
Conjugated polymer 102: Weight average molecular weight=72000
Conjugated polymer 103: Weight average molecular weight=118000
Conjugated polymer 104: Weight average molecular weight=48000
Conjugated polymer 105: Weight average molecular weight=55000
Conjugated polymer 106: Weight average molecular weight=37000
Conjugated polymer 107: Weight average molecular weight=28000
Conjugated polymer 108: Weight average molecular weight=39000
Conjugated polymer 109: Weight average molecular weight=43000
Conjugated polymer 110: Weight average molecular weight=29000
Conjugated polymer 110: Weight average molecular weight=33000
Conjugated polymer 112: Weight average molecular weight=28000
Conjugated polymer 113: Weight average molecular weight=40000
Conjugated polymer 114: Weight average molecular weight=37000
Conjugated polymer 201: Weight average molecular weight=36000
Conjugated polymer 202: Weight average molecular weight=29000

### Example 1-1

8 mg of the conjugated polymer 106 and 2 mg of CNT (ASP-100F, manufactured by Hanwha Nanotech Corp.) were added to 3.8 ml of ortho-dichlorobenzene, and the mixture was dispersed in an ultrasonic bath for 70 minutes. This mixed liquid was applied on a glass substrate and was heated at 80° C. for 30 minutes to distill off the solvent, and then the mixed liquid was dried at room temperature in a vacuum for 10 hours. Thus, a thermoelectric conversion layer having a film thickness of 1.9 μm was formed.

For the thermoelectric conversion layer thus obtained, the thermoelectric characteristics, liquid dispersibility and film-forming property were evaluated by the methods described below. The results are shown in Table 1.

### [Measurement of Thermoelectric Characteristics (ZT Value)]

With regard to the thermoelectric conversion layer as obtained, a Seebeck coefficient (unit: μV/K), at 100° C., and electrical conductivity (unit: S/cm) were evaluated using a thermoelectric characteristic measuring apparatus (RZ2001i, manufactured by OZAWA SCIENCE CO., LTD.). Then, thermal conductivity (unit: W/mK) was calculated using a thermal conductivity measuring apparatus (HC-074, manufactured by EKO Instruments Co., Ltd.). A ZT value at 100° C. was calculated according to the following numerical expression (A) using these values, and this ZT value was taken as thermoelectric characteristics.

Figure of merit ZT=S²σT/κ Numerical expression (A)

S(μV/K): Thermopower (Seebeck coefficient)

σ(S/cm): Electrical conductivity

κ(W/mK): Thermal conductivity

T(K): Absolute temperature

### [Evaluation of Liquid Dispersibility]

Solid components were dissolved or dispersed in a solvent; subsequently the resultant was left to stand for 5 minutes. The resultant was evaluated by visual observation of the occurrence of any precipitates or aggregates, and based on the following criteria for filterability by various membrane filters (material: PTFE) having pore diameters of 0.2 μm to 1.0 μm. For practical use, it is preferable to satisfy the criteria of A to C.

A: No precipitates or aggregates are observed by visual inspection, and filtration through a membrane filter having a pore diameter of 0.2 μm is enabled.

B: No precipitates or aggregates are observed by visual inspection, and filtration through a membrane filter having a pore diameter of 0.45 μm is enabled, but filtration at a pore diameter of less than 0.45 μm is difficult.

C: No precipitates or aggregates are observed by visual inspection, and filtration through a membrane filter having a pore diameter of 1 μm is enabled, but filtration at a pore diameter of less than 1 μm is difficult.

D: No precipitates or aggregates are observed by visual inspection, and filtration through a membrane filter having a pore diameter of 1 μm is difficult.

E: Precipitates or aggregates are observed by visual inspection.

### [Evaluation of Film-Forming Property]

Surface unevenness after coating and film drying was observed, and thus film-forming property was evaluated by the following criteria. The observation of surface unevenness of the film was carried out by measuring the surface roughness (Ra) using a probe type film thickness meter. For practical use, it is preferable to satisfy the criteria of A to C.

A: No coating unevenness is observed by visual inspection, and the surface roughness Ra of the film is less than 2.5 nm.

B: No coating unevenness is observed by visual inspection, and the surface roughness Ra of the film is more than or equal to 2.5 nm and less than 5 nm.

C: No coating unevenness is observed by visual inspection, and the surface roughness Ra of the film is more than or equal to 5 nm and less than 10 nm.

D: No coating unevenness is observed by visual inspection, and the surface roughness Ra of the film is more than or equal to 10 nm and less than 20 nm.

E: Severe coating unevenness is observed by visual inspection, and the surface roughness Ra of the film is 20 nm or more.

### Examples 1-2 to 1-3, Comparative Examples 1-1 to 1-4

Thermoelectric conversion layers of Examples 1-2 to 1-3 and Comparative Examples 1-1 to 1-4 were prepared and evaluated in the same manner as in Example 1-1, except that the kind of the conjugated polymer and the presence or absence of CNT were changed as indicated in Table 1. The results are shown in Table 1.

TABLE 1

| | | | Liquid | Film-forming | ZT value |
|---|---|---|---|---|---|
| | Conjugated polymer | CNT | dispersibility | property | (relative value) |
| Ex 1-1 | Conjugated polymer 106 | Presence | A | A | 231 |
| Ex 1-2 | Conjugated polymer 109 | Presence | A | A | 245 |
| Ex 1-3 | Conjugated polymer 110 | Presence | A | A | 228 |
| C Ex 1-1 | Conjugated polymer 1 | Presence | A | A | 93 |
| C Ex 1-2 | Conjugated polymer 4 | Presence | B | B | 89 |
| C Ex 1-3 | Conjugated polymer 3 | Absence | A | A | 4 |
| C Ex 1-4 | Conjugated polymer 4 | Absence | A | A | 6 |

Ex means Example.
C Ex means Comparative example.

As is clearly seen from Table 1, Examples 1-1 to 1-3 each containing CNT and a conjugated polymer having the particular repeating units, exhibited excellent liquid dispersibility, film-forming property and thermoelectric conversion performance (ZT values).

On the contrary, Comparative Examples 1-1 to 1-4 each using a conjugated polymer that did not have the particular repeating units, exhibited low thermoelectric conversion performance. Particularly, Comparative Examples 1-3 and 1-4 that did not contain CNT exhibited very low thermoelectric conversion performance.

### Example 2-1

3 mg of the conjugated polymer 101, 2 mg of CNT (ASP-100F, manufactured by Hanwha Nanotech Corp.), and 5 mg of polystyrene (430102 manufactured by Sigma-Aldrich Co.) as a non-conjugated polymer were added to 5 ml of ortho-dichlorobenzene, and the mixture was dispersed in an ultrasonic bath for 70 minutes. This mixed liquid was applied on a glass substrate and heated at 80° C. for 30 minutes to distill off the solvent, and then the mixed liquid was dried at room temperature in a vacuum for 10 hours. Thus, a thermoelectric conversion layer having a film thickness of 2.1 μm was formed.

For the thermoelectric conversion layer thus obtained, the moisture content, thermoelectric characteristics, liquid dispersibility, and film-forming property were evaluated by the methods described below. The results are shown in Table 1.

### [Measurement of Moisture Content]

The moisture content of the thermoelectric conversion layer was calculated by the Karl Fischer method, by dividing the amount of moisture (g) by the sample mass (g). Specifically, the thermoelectric conversion layer on a substrate was cut to a size of 5 cm×5 cm, this was dissolved in a Karl Fischer reagent, and the moisture content was measured using a moisture analyzer according to the Karl Fischer method (manufactured by Dia Instruments Co., Ltd.).

### Examples 2-2 to 2-20, Comparative Examples 2-1 to 2-10

Thermoelectric conversion layers of Examples 2-2 to 2-20 and Comparative Examples 2-1 to 2-10 were prepared and evaluated in the same manner as in Example 2-1, except that the kind and the presence or absence of the conjugated polymer or non-conjugated polymer, and the presence or absence of CNT were changed as indicated in Table 1. The results for the Examples are shown in Table 2-1, and the results for the Comparative Examples are shown in Table 2-2.

Meanwhile, as the carbonate compound for Examples 2-13 and 2-16, IUPIZETA PCZ-300 (trade name, manufactured by MITSUBISHI GAS CHEMICAL CO., INC.) was used, and as the imide compound for Example 2-14, SOLPIT 6,6-PI (trade name, manufactured by Solpit Industries, Ltd.) was used.

TABLE 2-1

| | | | | Moisture content | Liquid | Film-forming | ZT value |
|---|---|---|---|---|---|---|---|
| Ex | C p | N c p | CNT | (% by mass) | dispersibility | property | (relative value) |
| 2-1 | C p 101 | Polystyrene | Presence | 0.7 | A | A | 351 |
| 2-2 | C p 102 | Polystyrene | Presence | 1.1 | A | A | 259 |
| 2-3 | C p 103 | Poly (4-vinyl phenol) | Presence | 0.7 | A | A | 242 |
| 2-4 | C p 104 | Poly (2-vinyl naphthalene) | Presence | 0.7 | B | A | 370 |
| 2-5 | C p 105 | Poly (4-styrene sulfonate) | Presence | 0.8 | B | B | 367 |
| 2-6 | C p 106 | Poly (4-vinyl pyridine) | Presence | 0.9 | B | A | 373 |
| 2-7 | C p 107 | Poly (vinyl acetate) | Presence | 1.0 | B | A | 368 |
| 2-8 | C p 108 | Poly (N-vinyl carbazole) | Presence | 1.0 | A | A | 352 |
| 2-9 | C p 109 | Polylactic acid | Presence | 0.6 | A | A | 385 |
| 2-10 | C p 110 | Polystyrene | Presence | 0.6 | A | A | 298 |
| 2-11 | C p 111 | Polyvinylpyrrolidone | Presence | 0.9 | A | A | 283 |
| 2-12 | C p 104 | Butyl acrylate | Presence | 1.2 | A | A | 349 |
| 2-13 | C p 104 | Carbonate compound | Presence | 1.0 | A | A | 357 |
| 2-14 | C p 104 | Imide compound | Presence | 1.4 | B | A | 335 |
| 2-15 | C p 104 | Diphenyl siloxane | Presence | 1.3 | A | A | 347 |
| 2-16 | C p 112 | Carbonate compound | Presence | 0.9 | A | A | 317 |
| 2-17 | C p 113 | Polystyrene | Presence | 1.1 | A | A | 304 |
| 2-18 | C p 114 | Polylactic acid | Presence | 0.8 | A | A | 296 |
| 2-19 | C p 201 | Polystyrene | Presence | 1.0 | A | A | 194 |
| 2-20 | C p 202 | Polystyrene | Presence | 0.9 | A | A | 283 |

Ex means Example.
C p means Conjugated polymer.
N c p means Non-conjugated polymer.

TABLE 2-2

| | | | | Moisture content | Liquid | Film-forming | ZT value |
|---|---|---|---|---|---|---|---|
| C Ex | C p | N c p | CNT | (% by mass) | dispersibility | property | (relative value) |
| 2-1 | C p 1 | Polystyrene | Presence | 0.8 | B | B | 100 |
| | | | | | | | (Reference value) |
| 2-2 | C p 2 | Polystyrene | Presence | 1.1 | C | C | 98 |
| 2-3 | C p 3 | Polylactic acid | Presence | 1.0 | C | C | 88 |
| 2-4 | C p 4 | Polyvinylpyrrolidone | Presence | 0.6 | C | C | 110 |
| 2-5 | C p 5 | Poly (N-vinylcarbazole) | Presence | 0.9 | C | B | 125 |
| 2-6 | C p 6 | Poly (4-vinylpyridine) | Presence | 0.9 | A | A | 106 |
| 2-7 | C p 7 | Polylactic acid | Presence | 1.1 | A | A | 92 |
| 2-8 | Absence | Polystyrene | Presence | 0.8 | E | E | 36 |
| 2-9 | C p 102 | Polystyrene | Absence | 0.9 | A | A | 8 |
| 2-10 | C p 102 | Absence | Absence | 1.0 | A | A | 5 |

C Ex means Comparative example.
C p means Conjugated polymer.
N c p means Non-conjugated polymer.

As is clearly seen from Table 2-1, Examples 2-1 to 2-20 each containing a conjugated polymer having the particular repeating units, a non-conjugated polymer and CNT, exhibited excellent liquid dispersibility, film-forming property and thermoelectric conversion performance (ZT values).

On the contrary, Comparative Examples 2-1 to 2-7 each using a conjugated polymer that did not have the particular repeating units, exhibited low thermoelectric conversion performance, and many of them exhibited inferior liquid dispersibility and film-forming property as compared with Examples. Furthermore, Comparative Examples 2-8 to 2-10, each of which did not contain any one of a conjugated polymer, a non-conjugated polymer and CNT, exhibited very low thermoelectric conversion performance.

### Examples 3-1 to 3-5

Thermoelectric conversion layers were prepared and evaluated in the same manner as in Example 2-1, except that the kind of the conjugated polymer was changed from conjugated polymer 101 to conjugated polymer 103, the solvent was changed to a mixed solvent of tetrahydrofuran 5 vol % and chloroform 95 vol % instead of ortho-dichlorobenzene, and the solvent distill-off time at room temperature in a vacuum after coating was changed as indicated in Table 3. Meanwhile, in the case of using a dehydrated solvent, dehydrated tetrahydrofuran (manufactured by Wako Pure Chemical Industries, Ltd.) and dehydrated chloroform (manufactured by Wako Pure Chemical Industries, Ltd.) were used.

The results are shown in Table 3.

TABLE 3

| | | | Use of | Solvent | Moisture content | Liquid | Film-forming | ZT value |
|---|---|---|---|---|---|---|---|---|
| | C p | N c p | dehydration solvent | distill-off time | (% by mass) | dispersibility | property | (relative value) |
| Ex 3-1 | C p 103 | Polystyrene | Yes | 5 hours | 0.04 | A | A | 240 |
| Ex 3-2 | C p 103 | Polystyrene | No | 2 hours | 1.2 | A | A | 268 |
| Ex 3-3 | C p 103 | Polystyrene | No | 20 minutes | 13.7 | C | B | 271 |
| Ex 3-4 | C p 103 | Polystyrene | Yes | 48 hours | <0.01 | A | A | 175 |
| Ex 3-5 | C p 103 | Polystyrene | No | 5 minutes | 18 | B | A | 197 |

Ex means Example.
C p means Conjugated polymer.
N c p means Non-conjugated polymer.

As is clearly seen from Table 3, Examples 3-1 to 3-3 each having a moisture content in the range of 0.01% to 15.0% by mass, exhibited superior thermoelectric conversion performance (ZT values) than other Examples.

### Examples 4-1 to 4-5, Comparative Example 4-1

Thermoelectric conversion layers of Examples 4-1 to 4-5 and Comparative Examples 4-1 were prepared and evaluated in the same manner as in Example 2-1, except that the kind of the conjugated polymer was changed from conjugated polymer 101 to conjugated polymer 104, and the amounts of addition of the non-conjugated polymer and CNT relative to the conjugated polymer were changed as indicated in Table 4.

The results are shown in Table 4.

TABLE 4

| | C p | | N c p | | CNT | Moisture content | ZT value |
|---|---|---|---|---|---|---|---|
| | Kind | Amount of addition | Kind | Amount of addition | Amount of addition | (% by mass) | (relative value) |
| Ex 4-1 | C p 104 | 100 part by mass | Polystyrene | 14 part by mass | 29 part by mass | 0.8 | 207 |
| Ex 4-2 | C p 104 | 100 part by mass | Polystyrene | 300 part by mass | 100 part by mass | 0.9 | 351 |
| Ex 4-3 | C p 104 | 100 part by mass | Polystyrene | 1400 part by mass | 375 part by mass | 0.7 | 229 |
| Ex 4-4 | C p 104 | 100 part by mass | Polystyrene | 7 part by mass | 27 part by mass | 0.8 | 201 |
| Ex 4-5 | C p 104 | 100 part by mass | Polystyrene | 1600 part by mass | 425 part by mass | 1.1 | 205 |
| C Ex 4-1 | C p 104 | 100 part by mass | Absence | 0 part by mass | 25 part by mass | 1.0 | 42 |

Ex means Example.
C Ex means Comparative example.
C p means Conjugated polymer.
N c p means Non-conjugated polymer.

As is clearly seen from Table 4, Examples 4-1 to 4-3 each having a content of the non-conjugated polymer in the range of 10 parts to 1500 parts by mass relative to 100 parts by mass of the conjugated polymer, exhibited superior thermoelectric conversion performance (ZT values) than other Examples.

On the other hand, Comparative Example 4-1 in which no non-conjugated polymer was added, exhibited very low thermoelectric conversion performance.

### Examples 5-1 to 5-6

Thermoelectric conversion layers of Examples 5-1 to 5-6 were prepared and evaluated in the same manner as in Example 2-1, except that the kind of the conjugated polymer was changed to conjugated polymer 102, and 1 mg each of the dopant or thermal excitation assist agent indicated in Table 5 was added to the solvent. Meanwhile, in the case of using an onium salt compound as the dopant, the thermoelectric conversion layer after being dried was subjected to ultraviolet irradiation (amount of light: 1.06 J/cm²) using an ultraviolet irradiator (manufactured by EYE GRAPHICS CO., LTD., ECS-401GX), and doping was carried out.

The results are shown in Table 5.

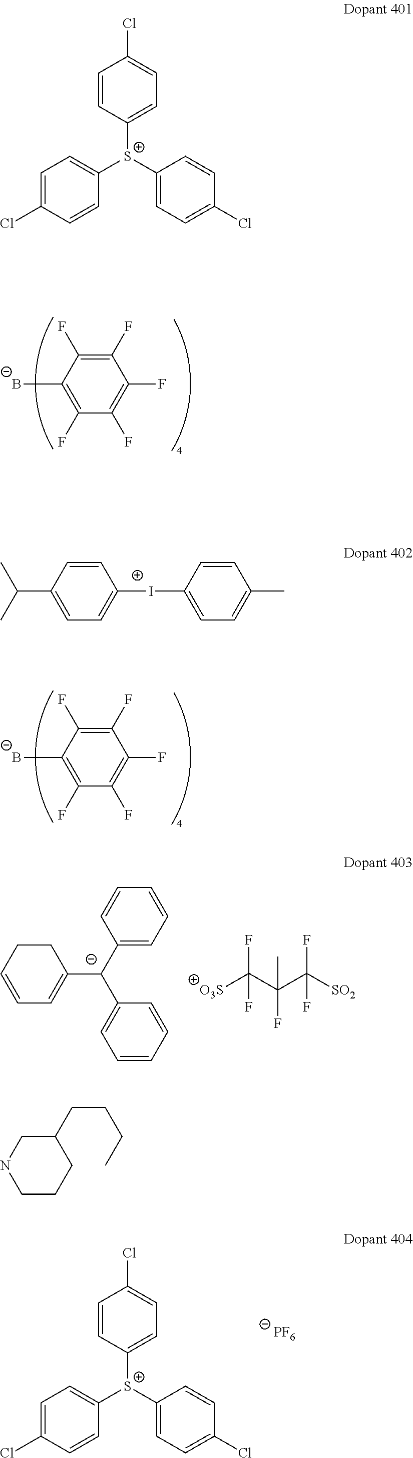

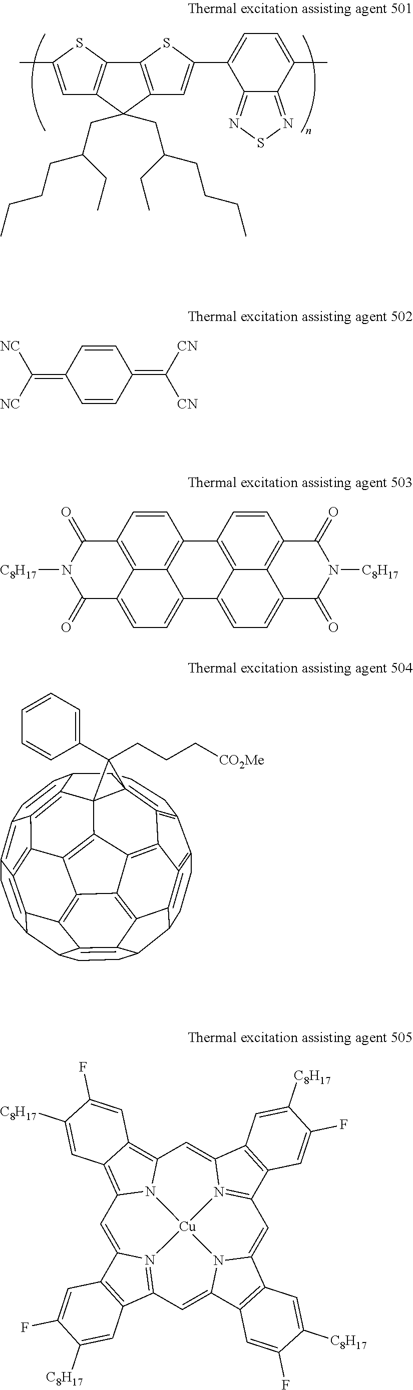

TABLE 5

| | | | | | Moisture content | Liquid | Film-forming | ZT value |
|---|---|---|---|---|---|---|---|---|
| | C p | N c p | Dopant | Thermal excitation assist agent | (% by mass) | dispersibility | property | (relative value) |
| Ex 5-1 | C p 102 | Polystyrene | Dopant 401 | Thermal excitation assist agent 505 | 0.8 | A | A | 439 |
| Ex 5-2 | C p 102 | Polystyrene | Dopant 402 | Thermal excitation assist agent 501 | 0.6 | A | A | 422 |
| Ex 5-3 | C p 102 | Polystyrene | Sulfuric acid | Thermal excitation assist agent 504 | 0.9 | B | C | 401 |
| Ex 5-4 | C p 102 | Polystyrene | Absence | Thermal excitation assist agent 502 | 1.0 | A | A | 388 |
| Ex 5-5 | C p 102 | Polystyrene | Dopant 403 | Thermal excitation assist agent 503 | 0.9 | A | A | 380 |
| Ex 5-6 | C p 102 | Polystyrene | Dopant 404 | Absence | 1.1 | A | A | 375 |

Ex means Example.
C p means Conjugated polymer.
N c p means Non-conjugated polymer.

As is clearly seen from Table 5, when any one of a dopant and a thermal excitation assist agent was incorporated, the thermoelectric conversion performance (ZT value) was enhanced. Furthermore, when onium salt compounds (dopants 401 to 404) were used as the dopant, excellent liquid dispersibility and film-forming property were obtained as compared with the case of using sulfuric acid.

### Example 6-1

A glass substrate (thickness: 0.8 mm) in which gold (thickness: 20 nm, width: 5 mm) are arranged on one surface as a first electrode, is used. On the electrode surface, the mixed liquid prepared in Example 1-1 was coated as a thermoelectric conversion material, by a drop casting method. The glass substrate was heated at 70° C. for 80 minutes to distill off the solvent, and then was dried at room temperature in a vacuum for 8 hours. Thereby, a thermoelectric conversion layer having a film thickness of 6.5 m and a size of 8 mm×8 mm was formed. Subsequently, on top of the thermoelectric conversion layer, a glass substrate having gold deposited thereon as a second electrode (thickness of electrode: 20 nm, width of electrode: 5 mm, and thickness of glass substrate: 0.8 mm) was superimposed at 80° C. such that the electrodes faced each other. Thus, a thermoelectric conversion element was produced. A temperature difference of 12° C. was applied between the substrate having the first electrode and the substrate having the second electrode, and it was confirmed using a voltage meter that a thermoelectromotive force of 836 pV was generated between the electrodes.

### Example 6-2

A thermoelectric conversion element was prepared in the same manner as in Example 6-1, except that a polyethylene terephthalate film (thickness: 125 μm) was used instead of a glass plate as the substrate having the first electrode, and a copper paste (trade name: ACP-080, manufactured by Asahi Chemical Research Laboratory Co., Ltd.) was used as the second electrode. A temperature difference of 12° C. was applied between the substrate having the first electrode and the second electrode, and it was confirmed using a voltage meter that a thermoelectromotive force of 790 μV was generated between the electrodes.

### Comparative Example 6-1

A thermoelectric conversion element was prepared in the same manner as in Example 6-1, except that the mixed liquid prepared in Comparative Example 1-1 was used as the thermoelectric conversion material. A temperature difference of 12° C. was applied between the substrate having the first electrode and the second electrode, and it was confirmed using a voltage meter that a thermoelectromotive force of 204 μV was generated between the electrodes.

As is clearly seen from the above results, Examples 6-1 and 6-2 each using a conjugated polymer having the particular repeating units, generated greater thermoelectromotive force as compared with Comparative Example 6-1 that did not use a conjugated polymer having the particular repeating units.

### Example 7-1

On a glass substrate having an ITO electrode (thickness: 10 nm) as a first electrode, the mixed liquid prepared in Example 1-1 was coated and was heated at 95° C. for 20 minutes to distill off the solvent, and then was dried at room temperature in a vacuum for 4 hours. Thus, a first thermoelectric conversion layer having a film thickness of 3.5 μm was formed. Subsequently, on the first thermoelectric conversion layer, the mixed liquid prepared in Example 1-2 was coated similarly and was heated at 95° C. for 20 minutes to distill off the solvent, and then was dried at room temperature in a vacuum for 4 hours. Thus, a second thermoelectric conversion layer was formed. As such, the first thermoelectric conversion layer and the second thermoelectric conversion layer were laminated, and as a result, a laminate type thermoelectric conversion layer having a film thickness of 6.8 μm in total was prepared.

On the second thermoelectric conversion layer, aluminum was provided by a vacuum deposition method as a second electrode (thickness of electrode: 20 nm), and thus a thermoelectric conversion element was produced.

### Example 7-2

A mixed liquid for a first thermoelectric conversion layer including the conjugated polymer 106, CNT and polystyrene was prepared in the same manner as in Example 2-1, except that the conjugated polymer was changed from 101 to 106. Furthermore, a mixed liquid for a second thermoelectric conversion layer including the conjugated polymer 109, CNT and polystyrene was prepared in the same manner as in Example 2-1, except that the conjugated polymer was changed from 101 to 109.

A thermoelectric conversion element was prepared in the same manner as in Example 7-1, except that these mixed liquids were used.

### Examples 7-3 to 7-7

Thermoelectric conversion elements were prepared in the same manner as in Example 7-2, except that the kinds of the conjugated polymer and the non-conjugated polymer were changed as indicated in Tables 6-1 and 6-2.

### Example 7-8

Mixed liquids for first, second and third thermoelectric conversion layers were prepared in the same manner as in Example 7-2, except that the kinds of the conjugated polymer and the non-conjugated polymer were changed as indicated in Table 6-2.

Using these mixed liquids, a first thermoelectric conversion layer, a second thermoelectric conversion layer, and a third thermoelectric conversion layer were coated in sequence on a first electrode to form films in the same manner as in Example 7-1, and a second electrode was further provided thereon to thereby produce a thermoelectric conversion element. The total film thickness of the thermoelectric conversion layer composed of three layers was 8.7 μm.

### Example 7-9

Mixed liquids for first, second, third and fourth thermoelectric conversion layers were prepared in the same manner as in Example 7-2, except that the kinds of the conjugated polymer and the non-conjugated polymer were changed as indicated in Table 6-2.

Using these mixed liquids, a first thermoelectric conversion layer, a second thermoelectric conversion layer, a third thermoelectric conversion layer, and a fourth thermoelectric conversion layer were coated in sequence on a first electrode to form films in the same manner as in Example 7-1, and a second electrode was further provided thereon to thereby produce a thermoelectric conversion element.

### Example 7-10

A mixed liquid A for a thermoelectric conversion layer contained the conjugated polymer 2, CNT and polylactic acid, and a mixed liquid B contained the conjugated polymer 107, CNT and polylactic acid were respectively prepared in the same manner as in Example 7-2.

In the same manner as in Example 7-1, a first thermoelectric conversion layer was formed using the mixed liquid A on a first electrode, a second thermoelectric conversion layer was formed using the mixed liquid B, a third thermoelectric conversion layer was formed using the mixed liquid A, and a fourth thermoelectric conversion layer was formed using the mixed liquid B in sequence. A second electrode was further provided thereon, and thus a thermoelectric conversion element was produced. The element thus obtained had a thermoelectric conversion layer employing a repeated structure such as first electrode-layer A-layer B-layer A-layer B-second electrode, and the total film thickness of the thermoelectric conversion layer composed of four layers was 9.7 μm.

### Example 7-11

A mixed liquid for a thermoelectric conversion layer was prepared in the same manner as in Example 7-2.

Using this mixed liquid, a first thermoelectric conversion layer was formed on a first electrode in the same manner as in Example 7-1, and a second electrode was further provided thereon to thereby produce a thermoelectric conversion element.

### Example 7-12

In the same manner as in Example 7-2, a mixed liquid contained the conjugated polymer 106, CNT and polystyrene, and a mixed liquid contained the conjugated polymer 109, CNT and polystyrene were prepared separately. An aliquot of the same weight was isolated from each of the mixed liquids, and the aliquots were mixed by ultrasonication for 10 minutes.

On a glass substrate having an ITO electrode (thickness: 10 nm) as a first electrode, this mixed liquid was coated and was heated at 95° C. for 20 minutes to distill off the solvent, and then was dried at room temperature in a vacuum for 4 hours. Thus, a single thermoelectric conversion layer having a film thickness of 6.0 μm, which did not have a laminate structure, was formed. Subsequently, aluminum was provided as a second electrode (thickness of electrode: 20 nm) in the same manner as in Example 7-1, and thus a thermoelectric conversion element was produced.

[Measurement of Thermoelectric Characteristics (Power Output)]

The thermoelectric characteristics of the thermoelectric conversion elements thus obtained were measured as described below.

The second electrode side of a thermoelectric conversion element was attached onto a hot plate (manufactured by As One Corp., product No. HP-2LA) at a set temperature of 55° C., and a cold plate (manufactured by Nihon digital co., ltd., product No.: 980-127□L) at a set temperature of 25° C. was attached to the first electrode side. The power output (unit: W) of the thermoelectric conversion element was calculated by multiplying the thermoelectromotive force (unit: V) generated between the first electrode and the second electrode, and the current (unit: A), and this value was designated as the thermoelectric characteristic value.

The power outputs of the various elements were evaluated by indicating the power output values as relative values calculated by taking the power output value of the element of Example 7-11 as 100. The results are shown in Tables 6-1 to 6-3.

TABLE 6-1

| Thermoelectric conversion layer | | Example 7-1 | Example 7-2 | Example 7-3 | Example 7-4 | Example 7-5 |
|---|---|---|---|---|---|---|
| First layer | Conjugated polymer | 106 | 106 | 7 | 7 | 4 |
| | CNT | Presence | Presence | Presence | Presence | Presence |
| | Non-conjugated polymer | Absence | Polystyrene | Polystyrene | Polystyrene | Polylactic acid |
| Second layer | Conjugated polymer | 109 | 109 | 109 | 102 | 114 |
| | CNT | Presence | Presence | Presence | Presence | Presence |
| | Non-conjugated polymer | Absence | Polystyrene | Polystyrene | Polystyrene | Polylactic acid |

| | | | | | |
|---|---|---|---|---|---|
| Number of layers | Two | Two | Two | Two | Two |
| Film thickness of thermoelectric conversion | 6.8 μm | 7.3 μm | 6.5 μm | 7.1 μm | 8.0 μm |
| layer as a whole | | | | | |
| Output (relative value) | 225 | 384 | 437 | 422 | 379 |

TABLE 6-2

| Thermoelectric conversion | | Example | Example | Example | Example | Example |
|---|---|---|---|---|---|---|
| layer | | 7-6 | 7-7 | 7-8 | 7-9 | 7-10 |
| First | Conjugated | 111 | 7 | 2 | 1 | 2 |
| layer | polymer | | | | | |
| | CNT | Presence | Presence | Presence | Presence | Presence |
| | Non-conjugated | Carbonate | Polystyrene | Polyvinyl | Butyl | Polylactic |
| | polymer | compound | | pyrrolidone | acrylate | acid |
| Second | Conjugated | 114 | 111 | 103 | 105 | 107 |
| layer | polymer | | | | | |
| | CNT | Presence | Presence | Presence | Presence | Presence |
| | Non-conjugated | Absence | Polylactic | Polyvinyl | Butyl | Polylactic |
| | polymer | | acid | pyrrolidone | acrylate | acid |
| Third | Conjugated | | | 110 | 108 | 2 |
| layer | polymer | | | | | |
| | CNT | | | Presence | Presence | Presence |
| | Non-conjugated | | | Polyvinyl | Butyl | Polylactic |
| | polymer | | | pyrrolidone | acrylate | acid |
| Fourth | Conjugated | | | | 112 | 107 |
| layer | polymer | | | | | |
| | CNT | | | | Presence | Presence |
| | Non-conjugated | | | | Butyl | Polylactic |
| | polymer | | | | acrylate | acid |

| | | | | | |
|---|---|---|---|---|---|
| Number of layers | Two | Two | Three | Four | Four |
| Film thickness of | 7.5 μm | 7.6 μm | 8.7 μm | 9.2 μm | 9.7 μm |
| thermoelectric conversion | | | | | |
| layer as a whole | | | | | |
| Output (relative value) | 289 | 384 | 493 | 411 | 406 |

TABLE 6-3

| Thermoelectric conversion layer | | Example 7-11 | Example 7-12 |
|---|---|---|---|
| First layer | Conjugated polymer | 106 | 106 and 109 |
| | CNT | Presence | Presence |
| | Non-conjugated polymer | Polystyrene | Polystyrene |

| | | |
|---|---|---|
| Number of layers | One | One |
| Film thickness of thermoelectric | 5.8 μm | 6.0 μm |
| conversion layer as a whole | | |
| Output (relative value) | 100 | 89 |

As is clearly seen from Tables 6-1 to 6-3, the laminate type elements of Examples 7-1 to 7-10 each having plural thermoelectric conversion layers, exhibited higher power outputs (thermoelectric characteristics) as compared with the elements of Examples 7-11 and 7-12 each having a single thermoelectric conversion layer. Furthermore, from a comparison between Example 7-2 and Example 7-12, it was understood that the power output (thermoelectric characteristics) was enhanced by disposing different kinds of conjugated polymers in different layers.

Having described our invention as related to the present embodiments, it is our intention that the invention not be limited by any of the details of the description, unless otherwise specified, but rather be construed broadly within its spirit and scope as set out in the accompanying claims.

This application claims priority on Patent Application No. 2011-238781 filed in Japan on Oct. 31, 2011, Patent Application No. 2012-030836 filed in Japan on Feb. 15, 2012, Patent Application No. 2012-155982 filed in Japan on Jul. 11, 2012 each of which is entirely herein incorporated by reference.

### REFERENCE SIGNS LIST

1, 2, 3, 4 Thermoelectric conversion element
11, 17, 31, 37 Metal plate
12, 22, 32, 42 First substrate
13, 23, 33, 43 First electrode
14, 24 Thermoelectric conversion layer
34-a, 44-a First thermoelectric conversion layer
34-b, 44-b Second thermoelectric conversion layer
15, 25, 35, 45 Second electrode
16, 26, 36, 46 Second substrate

1. A thermoelectric conversion material, comprising a carbon nanotube and a conjugated polymer,
wherein the conjugated polymer at least has, as a repeating unit having a conjugated system,
(A) a condensed polycyclic structure in which three or more rings selected from hydrocarbon rings and heterocycles are condensed, and
(B) a monocyclic aromatic hydrocarbon ring structure, a monocyclic aromatic heterocyclic structure, or a condensed ring structure including the monocyclic structure.

2. The thermoelectric conversion material according to claim 1, wherein the repeating unit (B) is a monocyclic aromatic hydrocarbon ring structure, a monocyclic aromatic heterocyclic structure, or a condensed bicyclic structure including the monocyclic structure.

3. The thermoelectric conversion material according to claim 1, comprising a non-conjugated polymer.

4. The thermoelectric conversion material according to claim 1, wherein the conjugated polymer has a repeating unit represented by the following formula (1): 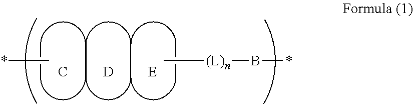
wherein in the formula (1), C and E each independently represent an aromatic hydrocarbon ring structure or an aromatic heterocyclic structure; D represents a hydrocarbon ring structure or a heterocyclic structure; the rings of C, D and E may each have a substituent; L represents —CH═CH—, —C≡C—, or —N═N—; n represents 0 or 1; B represents a monocyclic aromatic hydrocarbon ring structure, a monocyclic aromatic heterocyclic structure, or a condensed bicyclic structure including the monocyclic structure; and symbol * represents a linking site of the repeating unit.

5. The thermoelectric conversion material according to claim 1, wherein the conjugated polymer has a repeating unit represented by the following formula (2): 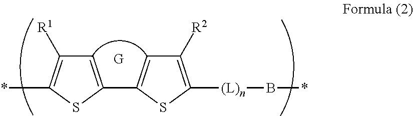
wherein in the formula (2), G represents a hydrocarbon ring structure or a heterocyclic structure; the ring G may have a substituent; R¹ and R² each independently represent a hydrogen atom or a substituent; and L represents —CH═CH—, —C≡C—, or —N═N—; n represents 0 or 1; B represents a monocyclic aromatic hydrocarbon ring structure, a monocyclic aromatic heterocyclic structure, or a condensed bicyclic structure including the monocyclic structure; and symbol * represents a linking site of the repeating unit.

6. The thermoelectric conversion material according to claim 1, wherein the conjugated polymer has a repeating unit represented by the following formula (3): 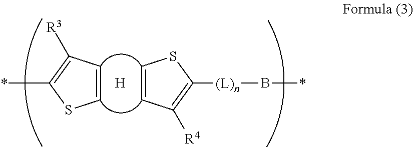
wherein in the formula (3), H represents a hydrocarbon ring structure or a heterocyclic structure; the ring H may have a substituent; R³ and R⁴ each independently represent a hydrogen atom or a substituent; and L represents —CH═CH—, —C≡C—, or —N═N—; n represents 0 or 1; B represents a monocyclic aromatic hydrocarbon ring structure, a monocyclic aromatic heterocyclic structure, or a condensed bicyclic structure including the monocyclic structure; and symbol * represents a linking site of the repeating unit.

7. The thermoelectric conversion material according to claim 4, wherein in the formula (1), the central ring of the condensed tricyclic structure is substituted with a linear or branched alkyl group.

8. The thermoelectric conversion material according to claim 4, wherein in the formula (1), B represents a thiophene ring structure, a benzene ring structure, or a condensed bicyclic structure including the thiophene or benzene ring structure.

9. The thermoelectric conversion material according to claim 1, wherein the molar ratio of the repeating units (A) and (B) in the conjugated polymer is 1:1.

10. The thermoelectric conversion material according to claim 3, wherein the non-conjugated polymer is a polymeric compound formed by polymerizing a compound selected from the group consisting of a vinyl compound, a (meth)acrylate compound, a carbonate compound, an ester compound, an amide compound, an imide compound, and a siloxane compound.

11. The thermoelectric conversion material according to claim 1, comprising a solvent, wherein the thermoelectric conversion material is formed by dispersing the carbon nanotubes in the solvent.

12. The thermoelectric conversion material according to claim 1, comprising a dopant.

13. The thermoelectric conversion material according to claim 1, comprising a thermal excitation assist agent.

14. The thermoelectric conversion material according to claim 12, wherein the dopant is an onium salt compound.

15. The thermoelectric conversion material according to claim 1, wherein the moisture content of the thermoelectric conversion material is from 0.01% by mass to 15% by mass.

16. A thermoelectric conversion element, using the thermoelectric conversion material according to claim 1 in a thermoelectric conversion layer.

17. The thermoelectric conversion element according to claim 16, comprising two or more thermoelectric conversion layers, wherein at least one layer of the thermoelectric conversion layers contains the thermoelectric conversion material according to claim 1.

18. The thermoelectric conversion element according to claim 17, wherein among the two or more thermoelectric conversion layers, adjacent thermoelectric conversion layers contain conjugated polymers that are different from each other.

19. The thermoelectric conversion element according to claim 16, comprising a substrate and the thermoelectric conversion layer provided on the substrate.

20. The thermoelectric conversion element according to claim 16, further comprising electrodes.

21. An article for thermoelectric power generation, using the thermoelectric conversion element according to claim 16.

22. A carbon nanotube dispersion, comprising a carbon nanotube, a conjugated polymer, and a solvent,
wherein the carbon nanotubes are dispersed in the solvent, and
wherein the conjugated polymer at least has, as a repeating unit having a conjugated system,
(A) a condensed polycyclic structure in which three or more rings selected from hydrocarbon rings and heterocycles are condensed, and
(B) a monocyclic aromatic hydrocarbon ring structure, a monocyclic aromatic heterocyclic structure, or a condensed ring structure including the monocyclic structure.
